(19) United States
(12) Patent Application Publication
(10) Pub. No.: US 2010/0025722 A1
(43) Pub. Date: Feb. 4, 2010

(54) LIGHT EMITTING DEVICE, ITS MANUFACTURING METHOD AND ITS MOUNTED SUBSTRATE

(75) Inventor: Naoki Wada, Ehime-ken (JP)

Correspondence Address: PEARNE & GORDON LLP, 1801 EAST 9TH STREET, SUITE 1200, CLEVELAND, OH, 44114-3108, US

(73) Assignee: HARISON TOSHIBA LIGHTING CORP., Ehime-ken (JP)

(21) Appl. No.: 12/514,619

(22) PCT Filed: Aug. 31, 2007
(86) PCT No.: PCT/JP2007/067073

§ 371 Date: May 13, 2009

(30) Foreign Application Priority Data
Nov. 14, 2006 (JP) 2006-308446
Dec. 26, 2006 (JP) 2006-350164
Jan. 31, 2007 (JP) 2007-021607

(51) Int. Cl. H01L 33/00; H01L 21/50

(52) U.S. Cl. 257/99; 438/26; 257/E33.056; 257/E21.499

(57) ABSTRACT

A light emitting device according to the invention includes: a package including a generally quadrangular light emitting surface with a recess formed therein, a rear surface opposed to the light emitting surface, a first side surface generally orthogonal to the light emitting surface and the rear surface, and a second side surface opposed to the first side surface; and a light emitting element provided in the recess. At least one of the first side surface and the rear surface include a first and second feeder electrode surfaces and a mounting surface provided between the first feeder electrode surface and the second feeder electrode surface. A step difference is provided between the first feeder electrode surface and the mounting surface, and a step difference is provided between the second feeder electrode surface and the mounting surface. The first and second feeder electrode surfaces are set back from the mounting surface adjacent thereto. This structure is possible to make a light emitting device high in brightness and thin in thickness.

### TECHNICAL FIELD

This invention relates to a light emitting device, its manufacturing method and its mounted substrate, and more particularly to a side view type light emitting device which can be used for a backlight of a liquid crystal display (LCD), for example, and its manufacturing method and its mounted substrate.

Additionally, this invention relates to a light emitting device, and more particularly to a light emitting device in which a light emitting element is housed in a recess of a package to emit light from the recess and prevent light leakage from other than the recess.

### BACKGROUND ART

Some of the light emitting devices used by being mounted on a mounting member such as a substrate are “side view type” light emitting devices which emit light in a direction generally parallel to the mounting surface (e.g., Patent Documents 1 and 2). The side view type light emitting device can be used in various applications, such as illumination, display, and signal transmission. For example, if the side view type light emitting device is used for a backlight of a liquid crystal display (LCD), light can be introduced into a light guide plate constituting the backlight from its side surface, allowing a small and highly efficient backlight to be realized.

On the other hand, some light emitting devices used for illumination, various displays, optical communication, or a backlight of a liquid crystal display device, for example, have a structure in which a light emitting element such as an LED (light emitting diode) is housed in a recess of a package made of a resin, ceramic or the like. One example thereof is a surface mount type light emitting device (surface mounted device, SMD).

As a light emitting device like this, for example, a package for housing a light emitting element is disclosed, in which a light emitting element is mounted in a recess of a ceramic package, and the inner side surface of the recess is coated with a metal layer (Patent Document 3). Furthermore, a light emitting diode package is disclosed, in which a light emitting element is mounted in a recess of a ceramic package, and a metallic ring is brazed around the light emitting element so that this ring is used as a reflecting mirror (Patent Document 4).

### Patent Document 1: JP-A-2004-207688

### Patent Document 2: JP-A-2006-229007

### Patent Document 3: JP-A-2002-232017

### Patent Document 4: JP-A-2005-243658

### DISCLOSURE OF INVENTION

### Problems to be Solved by the Invention

In the recent market trend, side view type light emitting devices have been also required to have higher brightness. However, increased brightness results in increased temperature of the mounted semiconductor light emitting element, which causes problems such as the decrease of light emission efficiency of the semiconductor light emitting element and the decrease of reflectance of the resin constituting the package.

Furthermore, in the recent market trend, liquid crystal displays have been also required to have thinner profile. To meet this requirement, an ultrathin side view type light emitting device is about to be needed, in which the light emitting surface has a height of e.g. 1 millimeter or less.

On the other hand, in view of the distribution characteristics of light emitted from the light emitting device, use of a metal for a reflecting layer may result in insufficient uniformity, because the light is reflected under the condition similar to the specular reflection and the reflected light could be unevenly distributed in a particular direction. To achieve more uniform light distribution, it is desirable to use diffuse reflection obtained by the reflecting surface of a resin or ceramic, rather than a metal.

However, a resin or ceramic transmits e.g. approximately 20 to 30 percent of the light emitted from the light emitting element. That is, the light is not reflected by the inner sidewall of the recess surrounding the light emitting element, decreasing the light intensity in the emitting direction. In particular, with the recent downsizing of light emitting devices, the thickness from the inner sidewall of the recess to the outer wall of the light emitting device has been decreasing. Basically, light should be extracted only in the emitting direction of the recess. However, this decreased thickness is also about to cause a problem of light leakage in the lateral direction of the light emitting device.

This invention provides a light emitting device allowing higher brightness and thinner profile, and its manufacturing method and its mounted substrate.

Additionally, this invention provides a light emitting device capable of efficiently emitting light in the emitting direction by using a diffuse reflecting surface and preventing light leakage from the package.

### Means for Solving the Problems

According to an aspect of the invention, there is provided a light emitting device including: a package including a generally quadrangular light emitting surface with a recess formed therein, a rear surface opposed to the light emitting surface, a first side surface generally orthogonal to the light emitting surface and the rear surface, and a second side surface opposed to the first side surface; and a light emitting element provided in the recess, at least one of the first side surface and the rear surface including a first and second feeder electrode surfaces connected to the light emitting element and a mounting surface provided between the first feeder electrode surface and the second feeder electrode surface, a step difference being provided between the first feeder electrode surface and the mounting surface, a step difference being provided between the second feeder electrode surface and the mounting surface, and the first and second feeder electrode surfaces being set back from the mounting surface adjacent thereto.

According to another aspect of the invention, there is provided a manufacturing method for a light emitting device which includes a package including a light emitting surface with a recess formed therein and a first side surface being generally orthogonal to the light emitting surface and having a first and second feeder electrode surfaces, and a light emitting element provided in the recess, the manufacturing method including: forming the first and second feeder electrode surfaces by forming a conductive layer on an inner wall of a plurality of through holes formed in a base body which includes the recess in a plurality.

According to another aspect of the invention, there is provided a manufacturing method for a light emitting device, including: forming a conductive layer on an inner wall of a through hole in a base body which includes the recess and a through hole in a plurality; mounting a light emitting element in the recess; connecting a lead electrode provided in the recess to the light emitting element by a bonding wire; filling the recess with a resin; and cutting the base body along a line connecting the through holes.

According to another aspect of the invention, there is provided a mounted substrate including: a substrate; a first and second land electrodes provided on the substrate; and the light emitting device according to any one of claims 1 to 4 provided on the substrate, the first feeder electrode surface of the light emitting device being connected to the first land electrode, and the second feeder electrode surface of the light emitting device being connected to the second land electrode.

According to another aspect of the invention, there is provided a light emitting device including: a package including a resin or ceramic with a recess formed therein; and a light emitting element provided in the recess, an outer wall surface of the resin or ceramic being provided with a reflecting film.

According to another aspect of the invention, there is provided a light emitting device including: a package made of a resin or ceramic and including a light emitting surface with a recess formed therein and a side surface adjacent to the light emitting surface; and a light emitting element provided in the recess, the side surface being provided with a reflecting film.

### BRIEF DESCRIPTION OF DRAWINGS

FIG. 1 is a schematic perspective view showing a light emitting device according to a first embodiment of the invention.

FIG. 2A is a cross-sectional view taken along line A-A of FIG. 1A, and FIG. 2B is a cross-sectional view taken along line B-B thereof.

FIG. 3 is a schematic view illustrating the mounted state of the light emitting device of this embodiment being in use as a side view type device.

FIG. 4 is a schematic view for illustrating the effect of correcting the mounting position of the light emitting device.

FIG. 5 is a flow chart showing the method for manufacturing a light emitting device of this embodiment.

FIG. 6 is a perspective view showing the light emitting device of this embodiment at an intermediate stage of manufacturing.

FIG. 7A is a cross-sectional view taken along line A-A of FIG. 6, and FIG. 7B is a cross-sectional view taken along line B-B of FIG. 6.

FIG. 8 is a schematic view showing the process of cutting out each light emitting device from the base body in which packages are continuously formed.

FIG. 9 is a schematic perspective view showing a variation of the light emitting device of this embodiment.

FIG. 10 is a schematic perspective view showing a variation of the light emitting device of this embodiment.

FIG. 11 is a schematic view for illustrating the effect of correcting the mounting position in the variation showed in FIG. 10.

FIG. 12 is a schematic perspective view showing another variation of the light emitting device of this embodiment.

FIG. 13 is a schematic perspective view showing another variation of the light emitting device of this embodiment.

FIG. 14 is a schematic perspective view showing another variation of the light emitting device of this embodiment.

FIG. 15 is a schematic perspective view showing another variation of the light emitting device of this embodiment.

FIG. 16 is a schematic perspective view showing another variation of the light emitting device of this embodiment.

FIG. 17 is a schematic plan view showing another variation of the light emitting device of this embodiment.

FIG. 18 is a schematic plan view showing another variation of the light emitting device of this embodiment.

FIG. 19 is a schematic plan view showing part of a process for manufacturing a light emitting device of the variation shown in FIG. 18.

FIG. 20 is a schematic plan view showing still another variation of the light emitting device of this embodiment.

FIG. 21 is a schematic plan view showing part of a process for manufacturing a light emitting device of the variation shown in FIG. 20.

FIG. 22 is a schematic perspective view showing a light emitting device according to a second embodiment of the invention.

FIG. 23 is a cross-sectional view taken along line A-A of FIG. 22A.

FIG. 24 is a schematic perspective view showing a light emitting device of a second example of this embodiment.

FIG. 25 is a cross-sectional view taken along line A-A of FIG. 24A.

FIG. 26 is a schematic perspective view showing a light emitting device of a third example of this embodiment.

FIG. 27 is a cross-sectional view taken along line A-A of FIG. 26A.

FIGS. 28A and 28B are schematic perspective views showing a light emitting device of a fourth and fifth example of this embodiment, respectively.

FIG. 29A is a schematic perspective view showing a light emitting device of a sixth example of this embodiment, and FIG. 29B is a cross-sectional view taken along line A-A thereof.

FIG. 30 is a schematic perspective view showing a light emitting device of a seventh example of this embodiment.

FIG. 31 is a schematic view showing the mounted state of the light emitting device of this example being in use as a side view type device.

FIG. 32 is a schematic perspective view showing a light emitting device of an eighth example of this embodiment.

FIG. 33 is a process view illustrating a method for forming the reflecting film 310 on the side surface of the package 301.

FIG. 34 is a process view showing a method for using a mask.

### DESCRIPTION OF REFERENCE NUMERALS

1a recess
1p protrusion
2a mounting surface electrode
2b light emitting surface electrode
2c rear surface electrode
2d upper surface electrode
3 semiconductor light emitting element
4 bonding wire
5a land electrode
5b lead electrode
6 through hole
9 heat dissipating metal
13 mounting surface electrode
14 light emitting surface electrode
15 rear surface electrode
16 resin
20 substrate
21 frame
50, 52 dicing line
100 mounting member
110 land electrode
120 solder
200 dicing blade
301 package
301a recess
301e exposed portion
301P projection
302a, 302b mounting electrode
303 light emitting element
304 bonding wire
305a, 305b lead electrode
305c connection via
309 heat sink metal
310 reflecting film
316 resin
320 substrate
321 frame
350 mask
400 mounting member
420 solder

### BEST MODE FOR CARRYING OUT THE INVENTION

Embodiments of the invention will now be described with reference to the drawings.

### First Embodiment

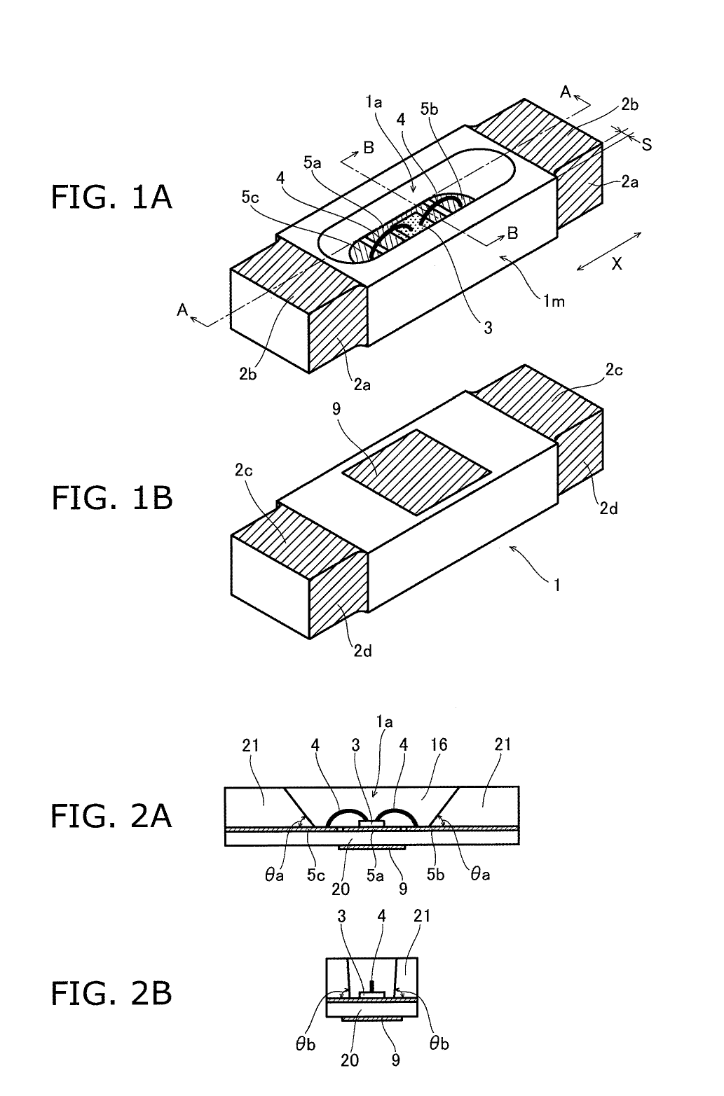

FIG. 1 is a schematic perspective view showing a light emitting device according to a first embodiment of the invention. More specifically, FIG. 1A is a perspective view of the light emitting device as viewed from the light extraction surface side, and FIG. 1B is a perspective view of the light emitting device as viewed from the side opposite to the light extraction surface.

FIG. 2A is a cross-sectional view taken along line A-A of FIG. 1A, and FIG. 2B is a cross-sectional view taken along line B-B thereof.

The light emitting device of this embodiment includes a package 1 shaped like a generally rectangular parallelepiped and including a recess 1a, and a semiconductor light emitting element 3 provided in the recess 1a. A land electrode 5a and lead electrodes 5b and 5c are provided on the bottom surface of the recess 1a. The semiconductor light emitting element 3 is mounted on the land electrode 5a. Electrodes (not shown) provided on the semiconductor light emitting element 3 are respectively connected to the lead electrodes 5b and 5c by bonding wires 4. The recess 1a is sealed with a translucent resin 16 such as epoxy or silicone. It is noted that FIG. 1 shows the state where the resin 16 is omitted.

At the left and right end of the package 1 shaped like a generally rectangular parallelepiped, the side surface orthogonal to the major surface (light emitting surface) having the recess 1a is provided with a pair of mounting surface electrodes (feeder electrode surfaces) 2a and 2a and a mounting surface 1m provided between these mounting surface electrodes 2a and 2a. An upper surface electrode 2d is provided on the surface opposed to the mounting surface electrode 2a. On the other hand, a light emitting surface electrode 2b is provided on the surface having the recess 1a, and a rear surface electrode 2c is provided on the surface opposed thereto (rear surface). Furthermore, a heat dissipating metal 9 may be provided on the surface opposite to the surface having the recess 1a.

As shown in FIGS. 2A and 2B, the package 1 includes a substrate 20 and a frame 21 provided thereon. The substrate 20 and the frame 21 can be each formed from a ceramic such as an alumina-based and mullite-based ceramic, glass ceramic, glass epoxy, paper phenol, or other thermosetting resin, UV (ultraviolet) curable resin, thermoplastic resin or the like. The substrate 20 is generally plate-like, and a hole 21a is formed in the frame 21. The recess 1a is formed by stacking the substrate 20 and the frame 21. The side surface of the recess 1a can serve as a light reflecting surface. That is, the uncoated material surface of the ceramic or resin constituting the frame 21 may be used to reflect light emitted from the semiconductor light emitting element 3. In this case, because the light undergoes diffuse reflection, a uniform diffuse reflecting surface can be formed.

On the other hand, to achieve a light condensing effect, a specular reflecting surface illustratively made of gold (Au) or silver (Ag) or a Bragg mirror based on a dielectric multilayer film may be formed on the side surface of the recess 1a.

The land electrode 5a and the lead electrodes 5b and 5c are insulated from each other and provided between the substrate 20 and the frame 21. The lead electrodes 5b and 5c extend to the left and right end of the package 1, and are connected to the mounting surface electrodes 2a and 2a provided on the outer surface of the package 1. That is, the left and right mounting surface electrodes 2a and 2a of the package 1 are connected to the two electrodes of the semiconductor light emitting element 3 through the lead electrodes 5b and 5c and the bonding wires 4 and 4.

In the light emitting device of this embodiment described above, first of all, the package 1 is made of a ceramic or the aforementioned resin material so as to realize a light emitting device having superior heat dissipation and being stably operable at high output. Conventionally, as a material of the package of such a light emitting device, thermoplastic resins suitable for injection molding, such as polyphthalamide (PPA), are widely used. However, in the case where such a thermoplastic resin is used, when the semiconductor light emitting element 3 is operated at high output, its heat generation and high-intensity light irradiation cause a problem of decreasing the reflectance of the resin surface. In contrast, according to this embodiment, the package 1 is made of a ceramic or the aforementioned thermosetting resin material. Hence, even if the semiconductor light emitting element 3 is operated at high output, the decrease of reflectance due to heat generation can be suppressed. In particular, use of a ceramic provides good heat dissipation and also suppresses the decrease of reflectance at the side surface of the recess 1a. Thus, a light emitting device being stably operable for a long period of time can be realized.

Furthermore, by providing the mounting surface electrode 2a, this embodiment can realize a side view type light emitting device which can be reliably and easily mounted on a mounting member such as a mounting substrate.

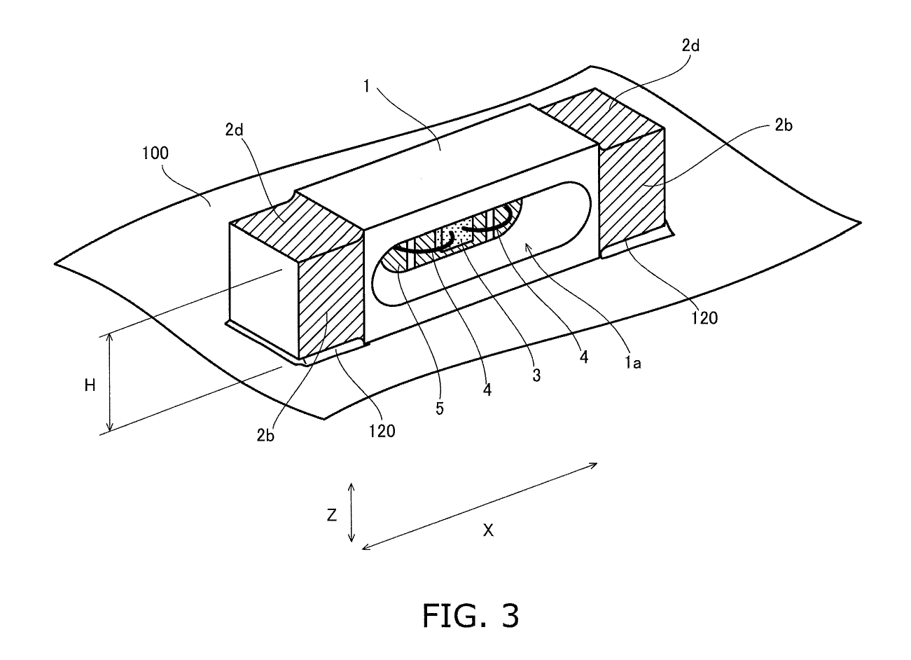

FIG. 3 is a schematic view illustrating the mounted state of the light emitting device of this embodiment being in use as a side view type device. In FIG. 3 and the following figures, the elements similar to those shown in earlier figures are labeled with the same reference numerals, and the detailed description thereof is omitted as appropriate.

In the case where the light emitting device of this embodiment is used as a side view type device, it can be mounted on a mounting member 100 such as a mounting substrate using a solder 120, with the mounting surface electrode 2a directed downward. According to this embodiment, in the mounted state like this, the height H of the package 1 can be reduced to 1 millimeter or less. For example, when in use as a backlight of a liquid crystal display, a light guide plate is adjacently juxtaposed at the frontside (opposed to the surface having the recess 1a) of the light emitting device thus mounted, and light emitted from the light emitting device is incident on the side surface of the light guide plate with high efficiency. Thus, an ultrathin, high-brightness backlight can be realized, in which the light guide plate and the light emitting device both have a thickness of 1 millimeter or less.

Furthermore, in the state where the light emitting device is thus mounted on the mounting member 100, a heat sink or the like, not shown, can be connected to the heat dissipating metal 9 provided on the side opposite to the recess 1a. Thus, heat dissipated from the semiconductor light emitting element 3 can be efficiently dissipated outside through the large heat dissipating metal 9 provided immediately on the backside thereof.

For use as a backlight of a full-color liquid crystal display device, it is desirable to provide light emission with three colors of RGB (red, green, and blue). To this end, a plurality of light emitting devices including semiconductor light emitting elements of R, G, and B, respectively, may be placed at the side surface of the light guide plate. Alternatively, phosphors may be mixed into the resin 16 so that all or part of light emitted from the semiconductor light emitting element 3 is wavelength-converted into light emission of one of the RGB colors.

Furthermore, for use as a backlight of a liquid crystal display, for example, it is desirable to provide a uniform light distribution. To this end, first of all, the side surface of the recess 1a may be formed as a diffuse reflecting surface made of an uncoated material of the frame 21 as described above. Furthermore, as illustrated in FIG. 3, in the mounted state of the side view type, in order to efficiently introduce light into the side surface of the light guide plate, not shown, for example, the light distribution angle in the long side direction (X direction) is widened to 110 degrees or more, and the light distribution angle in the short side direction (Z direction) is narrowed to 100 degrees or less. To this end, preferably, the bevel angle θa of the side surface of the recess 1a is 50 degrees or less, and the bevel angle θb is 80 degrees or more (and 90 degrees or less).

On the other hand, this embodiment is also applicable to the so-called “top view type” by providing a rear surface electrode 2c in addition to the mounting surface electrode 2a. More specifically, the light emitting device may be mounted on the mounting member 100 as illustrated in FIG. 3 via the rear surface electrode 2c using a solder or the like so that it can be used as a top view type light emitting device which emits light generally upward with respect to the mounting surface. Also in this case, it has superior heat dissipation characteristics and is stably operable at high output.

Furthermore, according to this embodiment, a step difference S can be provided between the mounting surface and the mounting surface electrode 2a of the package 1. More specifically, as shown in FIG. 1, the mounting surface electrode 2a is set back by the height of the step difference S from the mounting surface of the package 1. The step difference S thus provided allows the package 1 to be in close contact with the mounting member 100 when it is mounted as a side view type device as shown in FIG. 3. More specifically, a solder 120 intervenes below the mounting surface electrode 2a provided with the step difference S, but does not intervene below the other mounting surface of the package 1, so that the package 1 can be mounted in close contact with the mounting member 100. That is, the package 1 can be mounted in close contact with the mounting member 100 without being lifted by the solder 120. Consequently, the height of the package 1 mounted on the mounting member 100 can be always maintained at a designed level, and the light extraction efficiency and coupling efficiency can be maintained at a high level.

Furthermore, according to this embodiment, the step difference S thus provided allows the solder to flow below the mounting surface electrode 2a so that the mounting position of the light emitting device can be automatically corrected to a prescribed position.

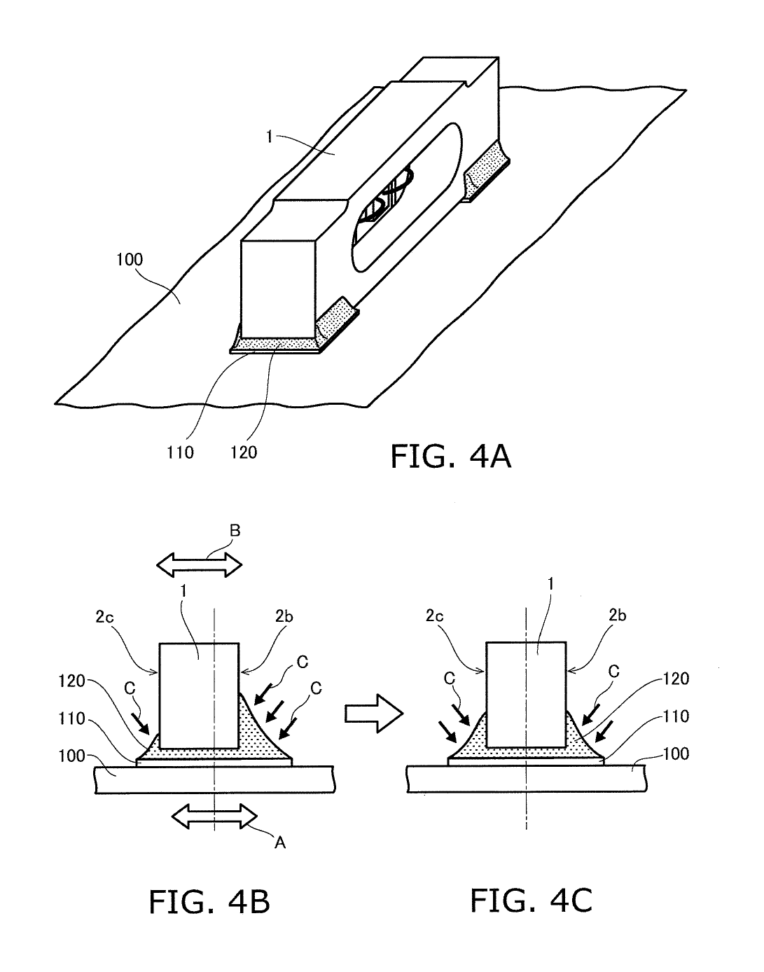

FIG. 4 is a schematic view for illustrating the effect of correcting the mounting position of the light emitting device.

The mounting member 100, such as a substrate, for mounting such a light emitting device is provided with a land electrode 110 corresponding to the mounting surface electrode 2a. In many cases, a solder material such as a cream solder is printed or applied on the land electrode 110. By heating with the light emitting device placed on the mounting member 100, the solder on the land electrode 110 is melted (reflowed) so that the mounting surface electrode 2a is connected to the land electrode 110 by the solder.

At this time, the step difference S thus provided allows the melted solder 120 to migrate between the land electrode 110 and the mounting surface electrode 2a as indicated by the arrow A. The melted solder 120 not only flows on the mounting surface electrode of the light emitting device, but also creeps up part of the light emitting surface electrode 2b and the rear surface electrode 2c, balancing with the surface tension C. As shown in FIG. 4B, if the light emitting device is displaced from the center of the land electrode 110, the amount of solder 120 on the light emitting surface electrode 2b side differs from the amount of solder 120 on the rear surface electrode 2c side. Then, the amount of creeping up of the solder on the light emitting surface electrode 2b also differs from that on the rear surface electrode 2c. Thus, the difference in the amount of solder 120 between the front and back (left and right) of the light emitting device creates weight imbalance and causes the solder 120 to migrate in the gap between the land electrode 110 and the mounting surface electrode 2a until the amount of solder 120 is balanced between the front and back. Consequently, as shown in FIG. 4C, the light emitting device is accordingly shifted to the left or right as indicated by the arrow B and automatically moved to the center of the land electrode 110. If the mounting position of the light emitting device is displaced, the optically designed coupling of light, for example, cannot be achieved. However, according to this embodiment, the light emitting device can be mounted automatically at the center of the pattern of the land electrode 110. Thus, the optical characteristics after mounting can be stably reproduced.

Preferably, the height of the step difference S, that is, the spacing between the land electrode 110 and the mounting surface electrode 2a, is at most approximately 0.3 millimeters. This is because, if the step difference S is higher than this, the solder 120 provided on the land electrode 110 may fail to reach the mounting surface electrode 2a. To reliably achieve the aforementioned correction effect described above with reference to FIG. 4, the light emitting surface electrode 2b and the rear surface electrode 2c are preferably formed at least partly adjacent to the mounting surface electrode 2a. This is because the solder 120 creeping up the light emitting surface electrode 2b and the rear surface electrode 2c creates front-back imbalance in weight to facilitate the migration of solder.

Here, to reliably achieve the effect of automatically correcting the mounting position as described above with reference to FIGS. 4B and 4C, preferably, the light emitting surface electrode 2b and the rear surface electrode 2c are both provided. If only the rear surface electrode 2c is provided, the solder 120 creeps up as shown in FIG. 4 on the rear surface electrode 2c side, but the solder 120 is less likely to creep up on the opposite side surface (the surface to be provided with the light emitting surface electrode 2b). Consequently, the amount of creeping up of the solder 120 differs between the rear surface side and the light emitting surface side. This interferes with the effect of automatically correcting the mounting position based on the weight balance of the solder 120 as described above with reference to FIGS. 4B and 4C. This also applies to the case, for example, where the light emitting surface electrode 2b is not provided, but only the rear surface electrode 2c is partly provided. Hence, in the case where the rear surface electrode 2c is provided, for example, it is preferable to also provide the light emitting surface electrode 2b opposed thereto so as to equalize the amount of creeping up of the solder 120 on these side surfaces. Then, the effect of automatically correcting the mounting position can be reliably achieved.

Furthermore, in the example shown in FIG. 1, both ends of the recess 1a of the package 1 are formed so as to be located on the inner side of the mounting surface electrode 2a as viewed in the direction of the arrow X (see FIG. 1). That is, they are formed so as to avoid interference between the recess 1a and the light emitting surface electrode 2b. Then, the light emitting surface electrode 2b can be reliably formed, and the aforementioned effect of automatically correcting the mounting position can be reliably achieved in combination with the rear surface electrode 2c.

In particular, as described above, in order to also enable use as a “top view type” device, the rear surface electrode 2c is also required in combination with the mounting surface electrode 2a. In this case, if the light emitting surface electrode 2b opposed to the rear surface electrode 2c is not provided, the creeping up of solder cannot be balanced, and it is difficult to achieve the effect of automatically correcting the mounting position. In contrast, in the example shown in FIG. 1, both ends of the recess 1a are formed so as to be located in the inner side of the mounting surface electrode 2a as viewed in the direction of the arrow X, and the upper surface electrode 2d opposed to the rear surface electrode 2c is provided. Thus, the solder is allowed to evenly creep up these electrodes 2c and 2d so that the effect of automatically correcting the mounting position can be reliably achieved. That is, by forming the recess 1a so that both ends of the recess 1a are located in the inner side of the mounting surface electrode 2a, it is possible to provide a light emitting device which can also be used as a “top view type” device while achieving the effect of automatically correcting the mounting position described above with reference to FIG. 4.

Next, a method for manufacturing a light emitting device of this embodiment is described.

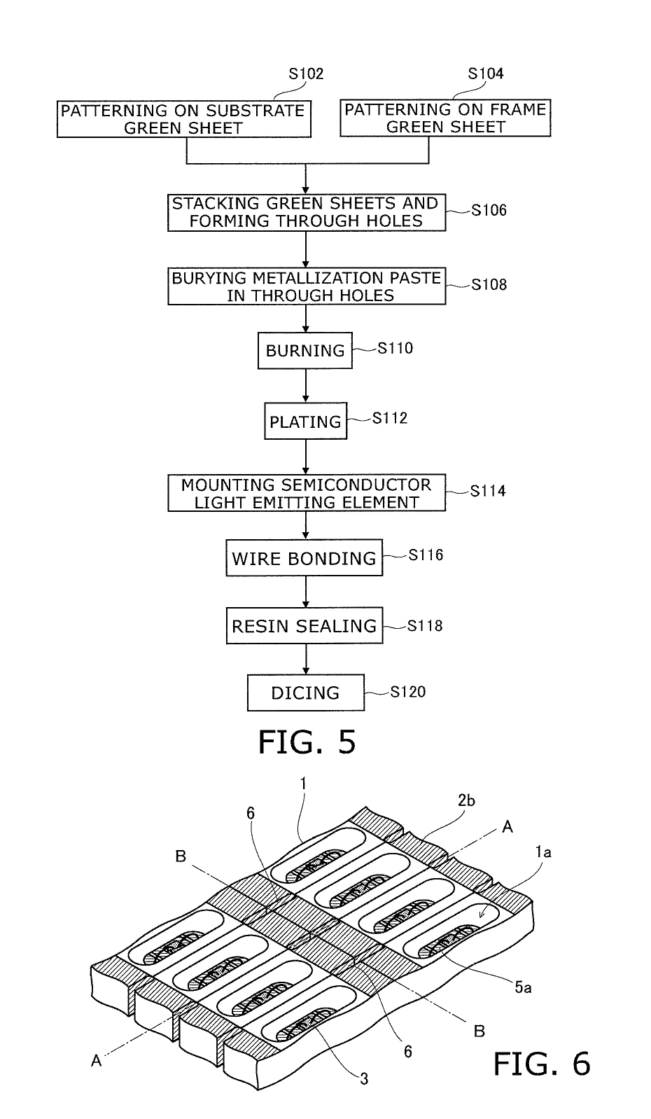

FIG. 5 is a flow chart showing the method for manufacturing a light emitting device of this embodiment.

FIG. 6 is a perspective view showing the light emitting device of this embodiment at an intermediate stage of manufacturing.

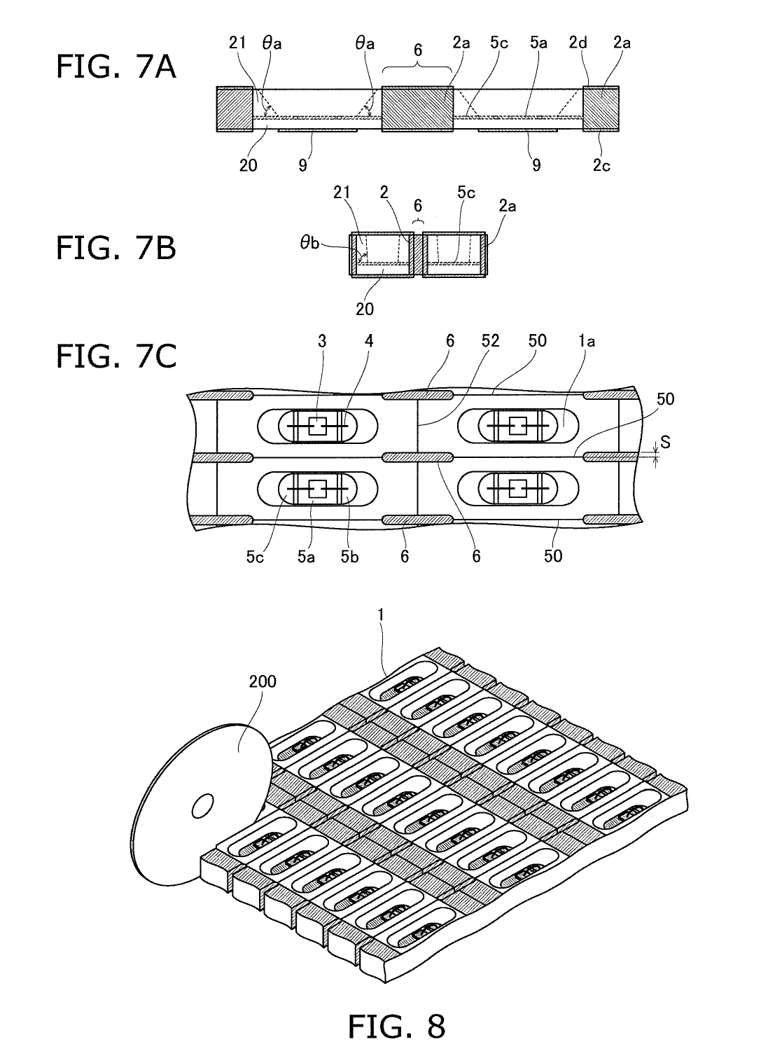

FIG. 7A is a cross-sectional view taken along line A-A of FIG. 6, FIG. 7B is a cross-sectional view taken along line B-B of FIG. 6, and FIG. 7C is a top view of the state shown in FIG. 6.

The light emitting device of this embodiment can be formed by stacking ceramic green sheets. More specifically, a green sheet for forming the substrate 20 and a green sheet constituting the frame 21 are used. It is noted that each of the substrate 20 and the frame 21 may be made of a plurality of green sheets.

On the surface of the green sheet for forming the substrate 20, a land electrode 5a and lead electrodes 5b and 5c are patterned illustratively by screen printing using a metallization paste (step S102). Likewise, on the rear surface of the green sheet forming the substrate 20, a rear surface electrode 2c, a heat dissipating metal 9 and the like are patterned. On the other hand, also on the green sheet for forming the frame 21, a light emitting surface electrode 2b is patterned illustratively by screen printing using a metallization paste (step S104).

Subsequently, the green sheet forming the substrate 20 is stacked on the rear surface of the green sheet forming the frame 21, then through holes 6 are formed (step S106), and a metallization paste is buried therein (step S108). Alternatively, it is also possible to form through holes 6 in each green sheet and bury a metallization paste therein before stacking the substrate 20 and the frame 21, and then these green sheets may be stacked. Subsequently, the stacked ceramic green sheets are burned at high temperature to form a sintered ceramic (step S110). Furthermore, the metal surface formed from the metallization paste is plated with nickel, gold, palladium, silver, platinum or the like to form a package 1 (step S112).

In this state, electrical continuity is established from the light emitting surface electrode 2b formed on the surface of the frame 21 to the rear surface electrode 2c on the rear surface side of the substrate 20 through the mounting surface electrode 2a and the upper surface electrode 2d. Furthermore, the lead electrodes 5b and 5c formed between the substrate 20 and the frame 21 are connected to the mounting surface electrode 2a.

Subsequently, a semiconductor light emitting element 3 is mounted on the land electrode 5a using a die attach material such as a gold-tin eutectic solder, a silver paste, a transparent resin, or a resin mixed with a reflecting material (step S114). Then, electrodes provided on the semiconductor light emitting element 3 are connected to the lead electrodes 5b and 5c by bonding wires 4 (step S116). Subsequently, the recess 1a is filled illustratively with an epoxy-based or silicone-based resin by potting, and cured at a prescribed temperature to form a resin 16 (step S118). Subsequently, this base body is diced along dicing lines 50 and 52 to cut out a light emitting device (step S120).

FIG. 8 is a schematic view showing the process of cutting out each light emitting device from the base body in which packages are continuously formed.

Each light emitting device can be separated by using a dicing blade 200 to cut between adjacent packages. Here, if the width 6W of the through hole 6 after metallization is larger than the thickness of the dicing blade 200, the dicing blade can be prevented from being in contact with the mounting surface electrode 2a, and the mounting surface electrode 2a can be protected.

As described above, according to this embodiment, green sheets with a metallized pattern formed thereon are stacked, through holes are formed, and its inside is metallized. Thus, the mounting surface electrode 2a for use in a side view type device can be reliably and easily formed.

Furthermore, in this embodiment, by adjusting the thickness of the dicing blade 200 and the dicing position, it is possible to regulate the height of the step difference S described above with reference to FIGS. 1 and 4. For example, in the case where the center of the through hole 6 is cut by the dicing blade 200, the following relationship holds among the width 6W of the through hole 6, the thickness 200t of the dicing blade 200, and the step difference S:

S=(6W−200t)/2

That is, the height of the step difference S can be reliably and easily regulated by suitably setting the width 6W of the through hole 6 and the thickness 200t of the dicing blade 200.

In the following, other features which can be given to the light emitting device of this embodiment are described. Although FIGS. 1 to 8 show a light emitting device including a semiconductor light emitting element 3 connected by two bonding wires 4, the invention is not limited thereto.

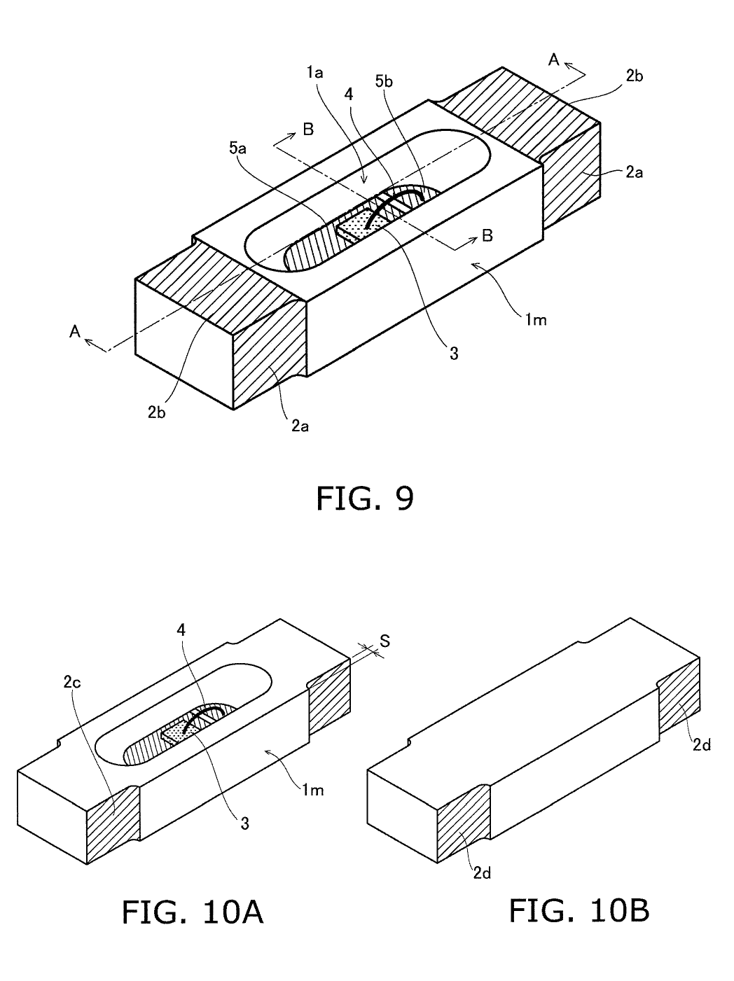

FIG. 9 is a schematic perspective view showing a variation of the light emitting device of this embodiment.

In this variation, the land electrode 5a provided between the substrate 20 and the frame 21 extends to one end of the package 1. Furthermore, the semiconductor light emitting element 3 is connected from its upper surface to the opposed lead electrode 5b by a bonding wire 4. That is, one electrode of this semiconductor light emitting element 3 is provided on the mounting surface side of the semiconductor light emitting element 3, and connected from the land electrode 5a to the mounting surface electrode 2a.

FIG. 10 is a schematic perspective view showing a variation of the light emitting device of this embodiment. More specifically, FIG. 10A is a perspective view of the light emitting device of this variation as viewed from the recess 1a side, and FIG. 10B is a perspective view as viewed from the side opposite to the recess 1a.

In this variation, at both ends of the package 1, only the mounting surface electrode 2a and the upper surface electrode 2d are provided, and the light emitting surface electrode 2b and the rear surface electrode 2c are not provided. That is, in the process described above with reference to FIGS. 6 and 7, no metallization pattern is formed on the rear surface of the green sheet of the substrate 20 and the upper surface of the green sheet of the frame 21. In this case, the metallization process can be omitted. Hence, the light emitting device can be provided at low cost by shortening the manufacturing process.

Furthermore, even in such cases where the light emitting surface electrode 2b and the rear surface electrode 2c are not provided, the effect of automatically correcting the mounting position of the light emitting device is achieved, like that described above with reference to FIG. 4.

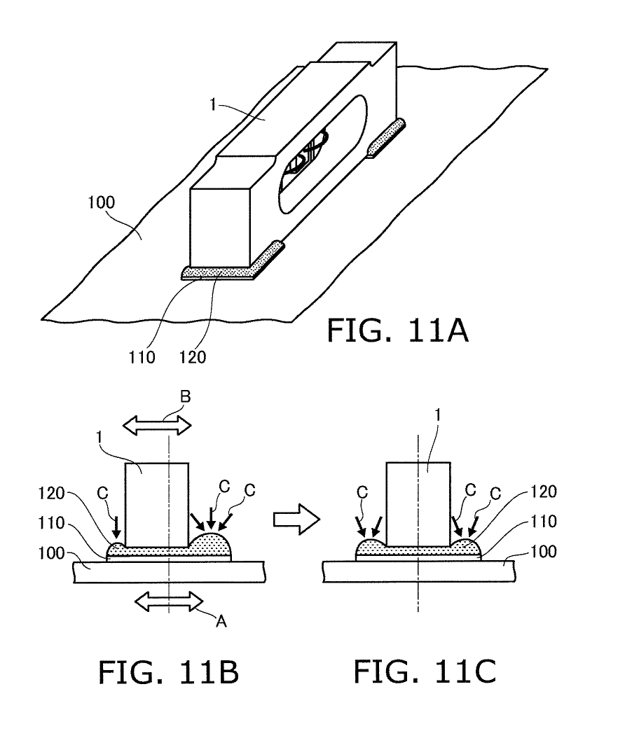

FIG. 11 is a schematic view for illustrating the effect of correcting the mounting position in this variation. In this variation, the light emitting surface electrode 2b and the rear surface electrode 2c are not provided. Hence, when the light emitting device is mounted with the mounting electrode 2a used as a mounting surface as shown in FIG. 11A, the solder 120 does not creep up the side surface of the package 1 made of a ceramic or the like. In such a case, as shown in FIGS. 11B and 1C, on both sides of the package 1, the melted solder 120 is bulged by the surface tension C on the land electrode 110. In this state, if the amount of solder 120 differs between the left and right of the package 1 as shown in FIG. 11B, the solder 120 flows below the package 1 by its self-weight so as to equalize its amount on the left and right as indicated by the arrow A. Consequently, as indicated by the arrow B in FIG. 11C, the package 1 is accordingly moved to the left or right and automatically aligned at the center of the land electrode 110.

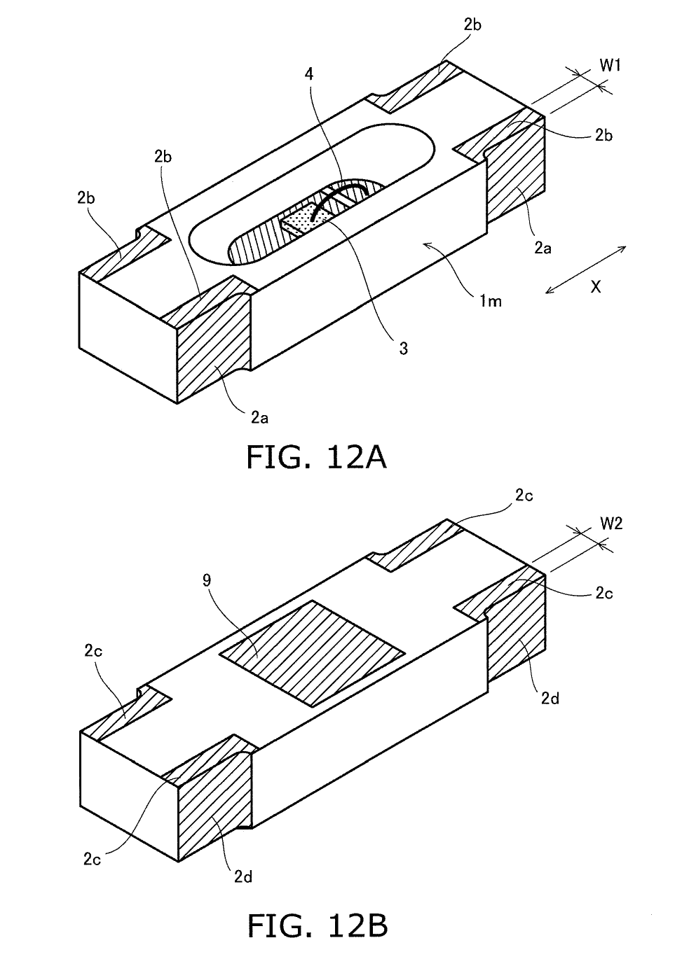

FIG. 12 is a schematic perspective view showing another variation of the light emitting device of this embodiment. More specifically, FIG. 12A is a perspective view of the light emitting device of this variation as viewed from the recess 1a side, and FIG. 12B is a perspective view as viewed from the side opposite to the recess 1a.

In this variation, at both ends of the package 1, the light emitting surface electrode 2b and the rear surface electrode 2c are each partly provided adjacent to the mounting surface electrode 2a and the upper surface electrode 2d. The light emitting surface electrode 2b and the rear surface electrode 2c thus provided allow the solder 120 to creep up as described above with reference to FIG. 4, and the effect of automatically correcting the mounting position of the light emitting device is achieved.

To this end, preferably, the width W1 of the light emitting surface electrode 2b and W2 of the rear surface electrode 2c are both larger than the amount of creeping up of the solder 120. More specifically, as shown in FIG. 4, in the case where the light emitting device is mounted with the mounting surface electrode 2a used as a mounting surface, the solder 120 creeps up each of the light emitting surface electrode 2b and the rear surface electrode 2c. To equalize the amount of creeping up of the solder 120 on these electrodes, preferably, the width W1 and the width W2 are both larger than the amount of creeping up of the solder. Here, the width W1 and the width W2 do not necessarily need to be equal as long as they are larger than the amount of creeping up of the solder 120.

Furthermore, the light emitting surface electrode 2b and the rear surface electrode 2c thus provided can prevent the light emitting device from being pulled down forward or backward by the melted solder 120 in the mounting process. More specifically, suppose that a surface mount type chip (such as a chip resistor and a chip capacitor) is mounted on an electrode of a printed circuit board with a cream solder screen-printed thereon, and then subjected to reflow soldering. If the amount of reflowed solder extremely differs between the left and right of the chip electrode, the electrode is not in contact with the solder because of mounting misalignment, or the temperature distribution in the reflow furnace is not uniform, then the side of the solder melted earlier acts as a base point, and the opposite side is lifted up, which is known as the “Manhattan phenomenon”. A phenomenon like this may occur also in the side view type light emitting device. If the amount of solder significantly differs between the left and right of the electrode of the light emitting device, the light emitting device may topple over by being pulled toward the solder melted earlier.

In contrast, according to this embodiment, the light emitting surface electrode 2b and the rear surface electrode 2c thus provided allow the melted solder to creep up these electrodes. Furthermore, as described above with reference to FIG. 4, the solder is allowed to migrate between the land electrode and the mounting surface electrode 2a. Thus, the solder is evenly balanced on both sides so that the chip can be prevented from toppling over.

Furthermore, also in this variation, both ends of the recess 1a of the package 1 are formed so as to be located in the inner side of the mounting surface electrode 2a as viewed in the direction of the arrow X, and thereby interference with the light emitting surface electrode 2b can be prevented. Consequently, by forming the rear surface electrode 2c and the light emitting surface electrode 2b to balance the creeping up of the solder, the mounting position can be automatically corrected. If both ends of the recess 1a extend close to both ends of the package 1, the light emitting surface electrode 2b needs to be formed between the recess 1a and the mounting surface electrode 2a. However, in the case where the package 1 is downsized, this space is too small to form the light emitting surface electrode 2b. In contrast, by providing the recess 1a on the inner side of the mounting surface electrode 2a, the light emitting surface electrode 2b can be reliably formed, and the effect of automatically correcting the mounting position can be reliably achieved.

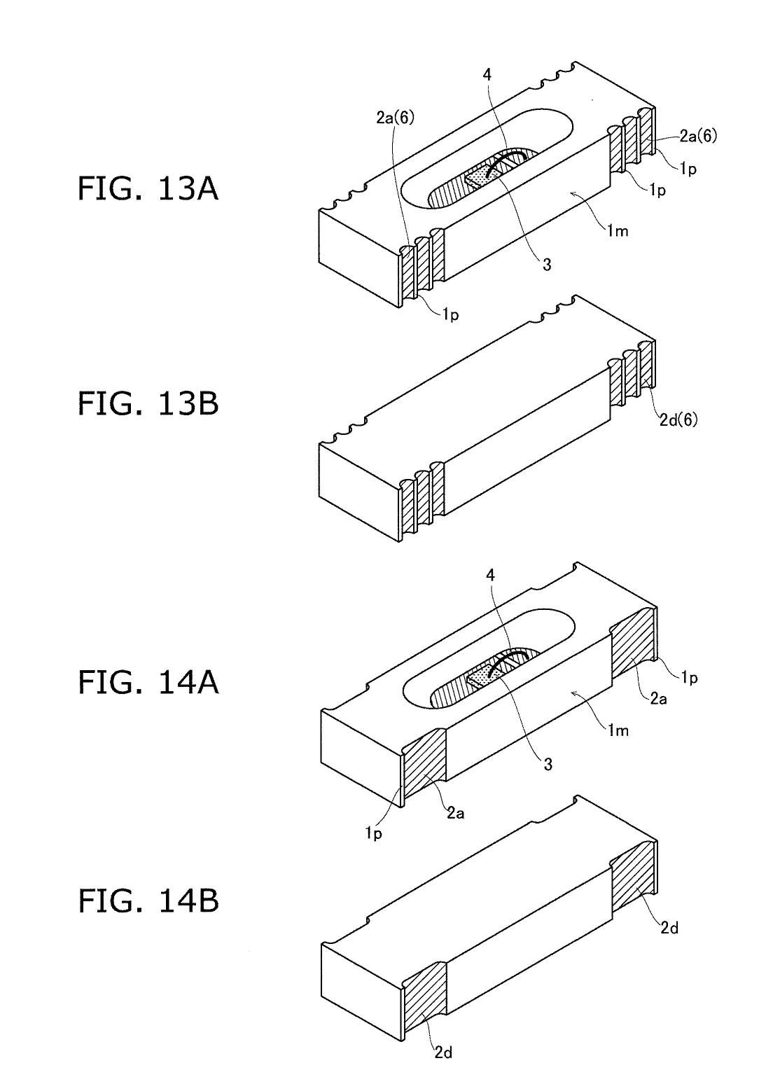

FIG. 13 is a schematic perspective view showing another variation of the light emitting device of this embodiment. More specifically, FIG. 13A is a perspective view of the light emitting device of this variation as viewed from the recess 1a side, and FIG. 13B is a perspective view as viewed from the side opposite to the recess 1a.

In this variation, a plurality of through holes 6 for forming the mounting surface electrode 2a is provided. That is, the mounting surface electrode 2a is divided by a protrusion 1p formed between the plurality of through holes 6. By thus providing a plurality of through holes 6 and metallizing the side surface thereof, the mounting surface electrode 2a having a large area can also be easily formed. Furthermore, the protrusion 1p between adjacent through holes 6 is coplanar with the mounting surface 1m of the package 1. That is, these protrusions 1p are in contact with the mounting surface of the mounting member and act as support legs. Consequently, the light emitting device can be stably installed upright in the side view state.

FIG. 14 is a schematic perspective view showing another variation of the light emitting device of this embodiment. More specifically, FIG. 14A is a perspective view of the light emitting device of this variation as viewed from the recess 1a side, and FIG. 14B is a perspective view as viewed from the side opposite to the recess 1a.

In this variation, the through hole 6 does not extend to both of the left and right ends, but a protrusion 1p is provided at both ends of the mounting surface 1m. Like the protrusion 1p described above with reference to FIG. 13, these protrusions 1p are coplanar with the mounting surface 1m of the package 1. That is, these protrusions 1p are in contact with the mounting surface of the mounting member and act as support legs. Consequently, the light emitting device can be stably installed upright in the side view state. That is, when mounted in the side view state as illustrated in FIG. 3, the light emitting device is supported at both ends of the package 1 by the protrusions 1p. Hence, longitudinal tilt of the package 1 can be prevented.

FIG. 15 is a schematic perspective view showing another variation of the light emitting device of this embodiment. More specifically, FIG. 15A is a perspective view of the light emitting device of this variation as viewed from the recess 1a side, and FIG. 15B is a perspective view as viewed from the side opposite to the recess 1a.

In this variation, a mounting surface electrode 13 is provided on the mounting surface 1m of the package 1. The mounting surface electrode 13 is illustratively connected to the land electrode 5a. In this light emitting device, for example, a three-electrode type semiconductor light emitting element can be installed. Alternatively, a plurality of semiconductor light emitting elements are mounted on the land electrode 5a, and the mounting surface electrode 13 is used as a common electrode for these semiconductor light emitting elements, so that the left and right mounting surface electrodes 2a and 2a can be used as a driving electrode of each semiconductor light emitting element. As an alternative use, a semiconductor light emitting element and a protective diode can be installed.

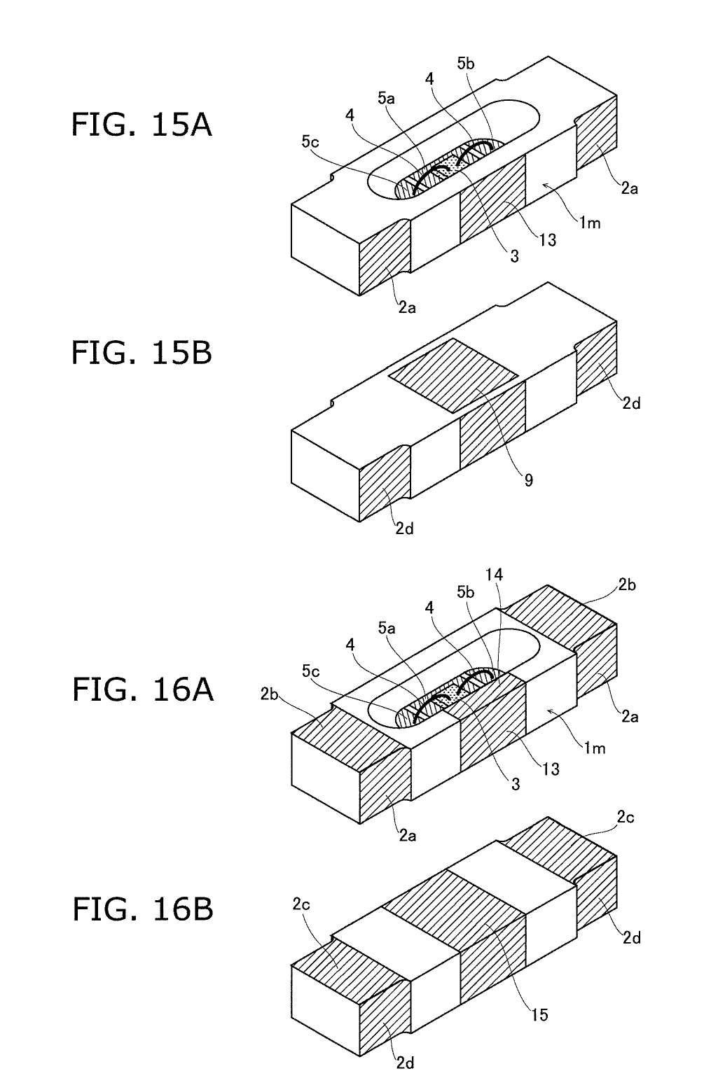

FIG. 16 is a schematic perspective view showing another variation of the light emitting device of this embodiment. More specifically, FIG. 16A is a perspective view of the light emitting device of this variation as viewed from the recess 1a side, and FIG. 16B is a perspective view as viewed from the side opposite to the recess 1a.

Also in this variation, a mounting surface electrode 13 is provided on the mounting surface 1m of the package 1. Furthermore, a light emitting surface electrode 14 connected to the mounting surface electrode 13 and extending on the front surface of the package 1, and a rear surface electrode 15 extending on the rear surface of the package 1 are provided.

The light emitting surface electrode 14 and the rear surface electrode 15 thus provided can prevent the light emitting device from being pulled down forward or backward by the melted solder 120 in the process of mounting the light emitting device on the mounting member. Furthermore, the rear surface electrode 15 in this variation can be used also as a heat dissipating metal. That is, it is possible to perform efficient heat dissipation from the rear surface electrode 15 provided on the backside of the semiconductor light emitting element 3.

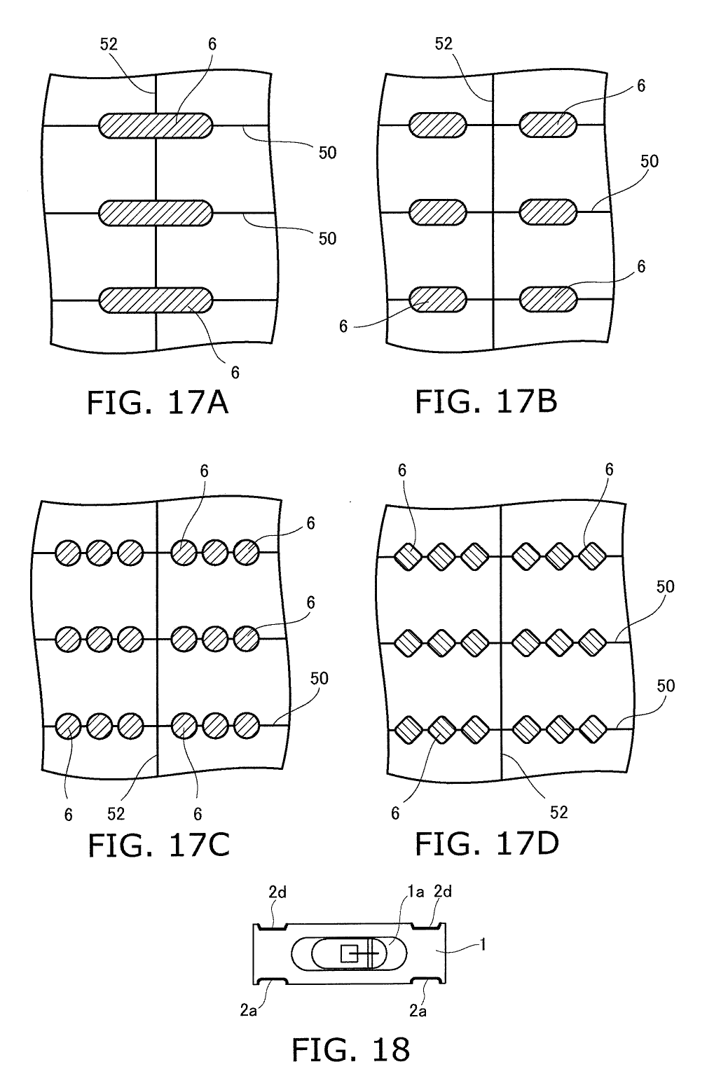

FIG. 17 is a schematic plan view showing another variation of the light emitting device of this embodiment. More specifically, this figure is a schematic view enlarging the intersection of dicing lines 50 and 52 on the upper surface of the frame 21 at an intermediate stage of manufacturing illustrated in FIG. 7C.

In this embodiment, the through hole 6 does not need to be provided singly, and the shape and spacing of such through holes can be arbitrarily selected. For example, as shown in FIG. 17A, a single flat through hole 6 may be used. Alternatively, as shown in FIG. 17B, flattish through holes 6 spaced from each other may be provided. Furthermore, as shown in FIG. 17C, a plurality of circular through holes 6 spaced from each other may be provided, or as shown in FIG. 17D, a plurality of generally quadrangular through holes 6 spaced from each other may be provided. In any case, the light emitting device of this embodiment can be formed by cutting along the dicing lines 50 and 52.

FIG. 18 is a schematic plan view showing another variation of the light emitting device of this embodiment.

In this variation, the shape of the mounting electrode (first feeder electrode surface, second feeder electrode surface) 2a is different from the shape of the upper surface electrode (third feeder electrode surface, fourth feeder electrode surface) 2d. More specifically, the mounting electrode 2a is dished in a curved surface configuration, whereas the upper surface electrode 2d is dished in a polygonal planar configuration. If the electrodes 2a and 2d are thus varied in shape, the polarity of the electrode is easy to distinguish. For example, in the face of the recess 1a of the light emitting device with the polygonal planar recess directed upward, the polarity can be easily distinguished, such as the anode is on the right side and the cathode is on the left side. Here, the polarity of the electrode can be distinguished as long as the shape of at least one of the left and right mounting electrode 2a and the left and right upper surface electrode 2d is different from the shape of the other electrodes, that is, the shape of one of these four electrodes is different from the shape of the other electrodes.

While the light emitting device of this embodiment may be mounted with the upper surface electrode 2d used as a mounting surface side, there is no trouble in mounting even if the recess provided with the upper surface electrode 2d has a polygonal planar configuration.

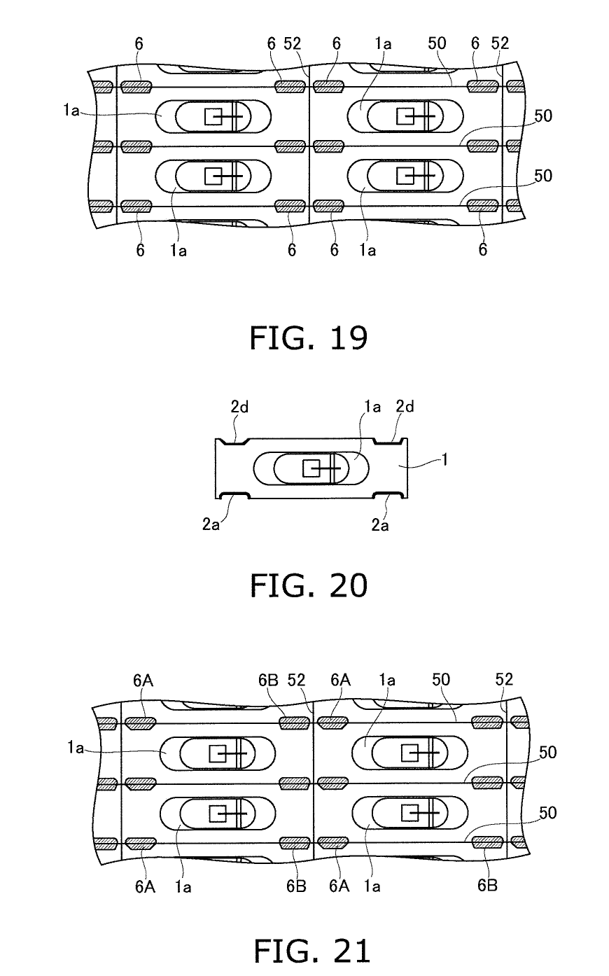

FIG. 19 is a schematic plan view showing part of a process for manufacturing a light emitting device of the variation shown in FIG. 18.

More specifically, like that described above with reference to FIGS. 6 to 8 and 17, the base body with a plurality of packages 1 formed therein is cut along the dicing lines 50 and 52, and thereby the light emitting device of this variation is obtained. Here, the opening shape of the through hole 6 is made asymmetric with respect to the dicing line 50, that is, the line connecting the through holes 6, so that the mounting surface electrode 2a and the upper surface electrode 2d can be varied in shape. In FIG. 19, the upper half of each through hole 6 constitutes the mounting surface electrode 2a, and the lower half of the through hole 6 constitutes the upper surface electrode 2d.

FIG. 20 is a schematic plan view showing still another variation of the light emitting device of this embodiment.

In this variation, of the two mounting electrodes (first feeder electrode surface, second feeder electrode surface) 2a and the two upper surface electrodes (third feeder electrode surface, fourth feeder electrode surface) 2d, two electrodes are each different in shape from any other electrode. That is, the shape of the mounting electrodes 2a is different from the shape of the upper surface electrodes 2d, and in addition, the upper surface electrodes 2d differ in shape between the left and right. Specifically, the upper surface electrode 2d on the left side in FIG. 20 has a configuration incised in a generally V shape, whereas the upper surface electrode 2d on the right side has a configuration incised in a generally trapezoidal shape. Thus, the left and right upper surface electrode 2d are varied in shape, which further facilitates distinguishing the polarity. For example, the anode is on the side incised in a V shape, and the cathode is on the side incised in a trapezoidal shape.

FIG. 21 is a schematic plan view showing part of a process for manufacturing a light emitting device of the variation shown in FIG. 20.

Also in this variation, the opening shape of the through holes 6A and 6B is made asymmetric with respect to the dicing line 50, that is, the line connecting the through holes 6A and 6B. Furthermore, the through hole 6A and the through hole 6B are varied in opening shape. Thus, the shape of each of the mounting surface electrode 2a and the upper surface electrode 2d can be formed. More specifically, in FIG. 21, the lower half of the through hole 6A corresponds to the upper surface electrode 2d incised in a V shape, and the lower half of the through hole 6B corresponds to the upper surface electrode 2d incised in a trapezoidal shape. By such a simple method, this variation can provide a light emitting device in which the polarity is very easy to distinguish.

There are other possibilities for facilitating distinguishing the polarity of the electrode. For example, the width of the left and right mounting surface electrode 2a or upper surface electrode 2d (the length as viewed in the direction of the arrow X in FIG. 1) may be varied, or the number and/or position of protrusions 1p as described above with reference to FIG. 13 may be varied between the left and right mounting surface electrode 2a. Alternatively, the protrusion 1p as described above with reference to FIG. 14 may be formed asymmetrically between the left and right.

The first embodiment of the invention has been described with reference to examples. However, the invention is not limited to these examples. For instance, those skilled in the art can suitably modify the substrate, frame, recess, semiconductor light emitting element, land electrode, lead electrode, mounting surface electrode, upper surface electrode, light emitting surface electrode, rear surface electrode, heat dissipating metal, wire, resin and the like constituting the light emitting device of the invention, and such modifications are also encompassed within the scope of the invention as long as they fall within the spirit of the invention.

Furthermore, the examples and variations can be combined with each other as long as technically feasible, and such combinations are also encompassed within the scope of the invention.

Furthermore, the light emitting device of this embodiment may also be formed using a printed circuit board. More specifically, first, through holes 6 are formed by die machining or NC (numerical control) drilling in a raw printed circuit board made of paper phenol or glass epoxy with copper or other electrode layers formed on the frontside and backside. The inner wall of this through hole 6 is metallized by plating or the like to form a mounting surface electrode 2a connected to the electrode layers formed on the frontside and backside of the printed circuit board. Next, the electrode layers formed on the frontside and backside of the printed circuit board are patterned to form an electrode pattern. Then, a semiconductor light emitting element is mounted on this electrode pattern, and the electrodes are wire-bonded. The semiconductor light emitting element and the wires are sealed or coated with resin or the like as needed. Subsequently, the printed circuit board is cut crisscross along the through holes 6. Thus, a side view type light emitting device is completed. In this case, the semiconductor light emitting element is mounted on the surface of the printed circuit board, and is sealed therearound illustratively with a sealing resin as needed.

### Second Embodiment

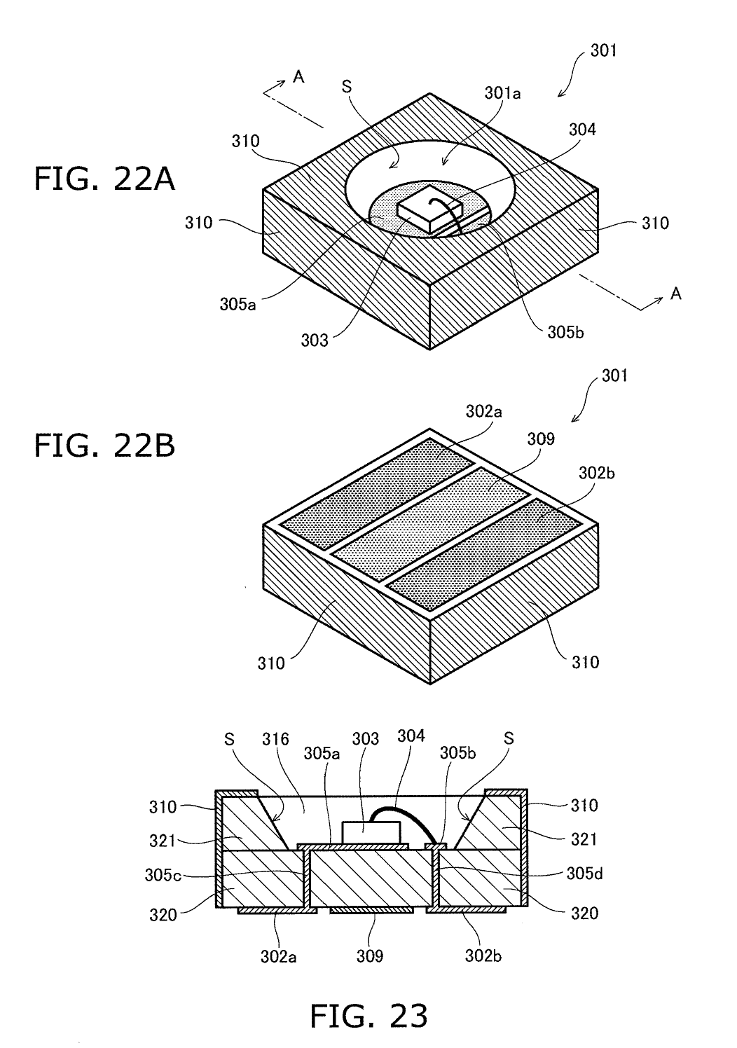

FIG. 22 is a schematic perspective view showing a light emitting device according to a second embodiment of the invention. More specifically, FIG. 22A is a perspective view of the light emitting device as viewed from the light extraction surface side, and FIG. 22B is a perspective view of the light emitting device as viewed from the side opposite to the light extraction surface.

FIG. 23 is a cross-sectional view taken along line A-A of FIG. 22A.

The light emitting device of this embodiment includes a package 301 shaped like a generally rectangular parallelepiped and including a recess 301a in the upper surface (light emitting surface), and a semiconductor light emitting element 303 provided in the recess 301a. Lead electrodes 305a and 305b are provided on the bottom surface of the recess 301a. The light emitting element 303, such as an LED, is mounted on the lead electrode 305a. An electrode (not shown) provided on the semiconductor light emitting element 303 is connected to the lead electrodes 305b by a bonding wire 304. The recess 301a is sealed with a translucent resin 316 such as epoxy or silicone. Here, phosphors may be dispersed in the resin 316 so that light emitted from the light emitting element 303 is wavelength-converted into white light. Alternatively, instead of dispersing such phosphors in the resin 316, the light emitting element 303 may be coated therewith on its upper surface or periphery. It is noted that, for convenience of illustration, FIG. 22 shows the state where the resin 316 is omitted.

On the rear surface side of the package 301 shaped like a generally rectangular parallelepiped, a pair of mounting electrodes (feeder electrode surfaces) 302a and 302b are provided, and a heat sink metal 309 for facilitating heat dissipation from the semiconductor light emitting element 303 is provided between these mounting electrodes 302a and 302b.

As shown in FIG. 23, the package 301 includes a substrate 320 and a frame 321 provided thereon. The substrate 320 and the frame 321 can be each formed from a ceramic such as an alumina-based and mullite-based ceramic, glass ceramic, glass epoxy, paper epoxy, paper phenol, thermosetting resin, UV (ultraviolet) curable resin, thermoplastic resin or the like. The substrate 320 is generally plate-like, and a hole is formed in the frame 321. The recess 301a is formed by stacking the substrate 320 and the frame 321. In the resin-based configuration, the substrate 320 and the frame 321 do not necessarily need to be separate bodies, but may be integrally molded.

The inner wall surface S of the recess 301a can serve as a light reflecting surface. That is, the uncoated material surface of the ceramic or resin constituting the frame 321 can be used as an inner wall surface S so that light emitted from the semiconductor light emitting element 303 is reflected by the inner wall surface S. In this case, because the light undergoes diffuse reflection, a uniform diffuse reflecting surface can be formed. This eliminates unevenness in the distribution characteristics of light emitted from the recess 301a, achieving uniform light distribution characteristics.

The lead electrodes 305a and 305b are insulated from each other and provided between the substrate 320 and the frame 321. The lead electrodes 305a and 305b extend to the rear surface of the package 301 through connection via 305c and 5d, and are connected to the mounting electrodes 302a and 302b provided on the rear surface of the package 301. That is, the mounting electrodes 302a and 302b on the rear surface of the package 301 are connected to the two electrodes of the semiconductor light emitting element 303 through the lead electrodes 305a and 305b.

Furthermore, in this embodiment, the outer wall surface of the package is covered with a reflecting film 310. More specifically, in the example shown in FIGS. 22 and 23, the upper surface and side surface of the package are covered with a reflecting film 310. Light emitted from the light emitting element 303 is reflected by the inner wall surface S of the recess 301a and extracted upward (toward the opening of the recess 301a). However, the inner wall surface S of the resin or ceramic does not have 100 percent reflectance for light emitted from the light emitting element 303. In particular, with the recent downsizing of light emitting devices, the thickness from the inner wall surface S to the outer wall surface (side surface) of the package 301 has been decreasing. For example, the reflectance of alumina-based ceramics reaches 80 percent or more for a thickness of approximately 1 millimeter, but decreases to approximately 60 percent for a thickness of 0.2 millimeters, causing a loss of approximately 20 percent in upward light extraction efficiency. The unreflected light leaks outside through the outer wall surface (such as the side surface) of the package 301. Furthermore, such light leakage to the basically unnecessary direction degrades the light distribution characteristics of the light emitting device, also causing concern about influence on the performance of equipment in which the light emitting device is installed.

In contrast, according to this embodiment, by covering the outer wall surface of the package 301 with a reflecting film 310, the light transmitted through the inner wall surface S and introduced into the frame 321 or the substrate 320 can be reflected back into the recess 301a and emitted outside. Consequently, even in the downsized light emitting device, light leakage from the outer wall surface of the package 301 is prevented, and light can be extracted from the recess 301a with high efficiency. Specifically, for example, even in a tiny package where the light emitting device is downsized to 1 millimeter or less, light leakage from the outer wall surface other than the recess 301a is prevented, and light can be extracted from the recess 301a with high brightness. Consequently, it is possible to realize a small, high-brightness, and high-performance light emitting device while maintaining desired light distribution characteristics.

The reflecting film 310 does not necessarily need to be in close contact with the outer wall surface of the package 301, but may be juxtaposed on the outer wall surface. Furthermore, the reflecting film 310 is preferably made of a material which has a higher reflectance than the substrate 320 and the frame 321 coated therewith. Specifically, the reflecting film 310 is illustratively formed from a metal such as silver, gold, aluminum, palladium, and platinum. Besides metals, it is also possible to use a resin and the like dispersed with fine particles of oxides such as titanium oxide and magnesium oxide. Furthermore, like an optical reflecting film for coating a lens and the like, a multilayer film made of dielectrics such as a metal oxide film may also be used as the reflecting film 310.

The reflecting film 310 formed from a metal or other conductive material is preferably formed so as to avoid short circuit to any of the mounting electrodes 302a and 302b. The device with short circuit to only one of the mounting electrodes 302a and 302b remains usable, but short circuit to both the mounting electrodes 302a and 302b makes the device unusable.

On the other hand, the reflecting film 310 formed from an insulator has no problem of electrical short circuit and the like. Hence, as shown in FIGS. 22 and 23, the reflecting film 310 can be provided on the outer wall surface of the package 301 so as to entirely cover the upper surface and the side surface.

Methods for forming the reflecting film 310 illustratively include the method of applying a paste containing a metal or metal oxide followed by burning, or the method of depositing a metal or dielectric multilayer film by evaporation, sputtering and the like. Furthermore, it is also possible to use the method of adhering a resin containing metal or metal oxide fine particles, and the method of sticking a metal foil, or a resin film and the like containing metal or metal oxide fine particles.

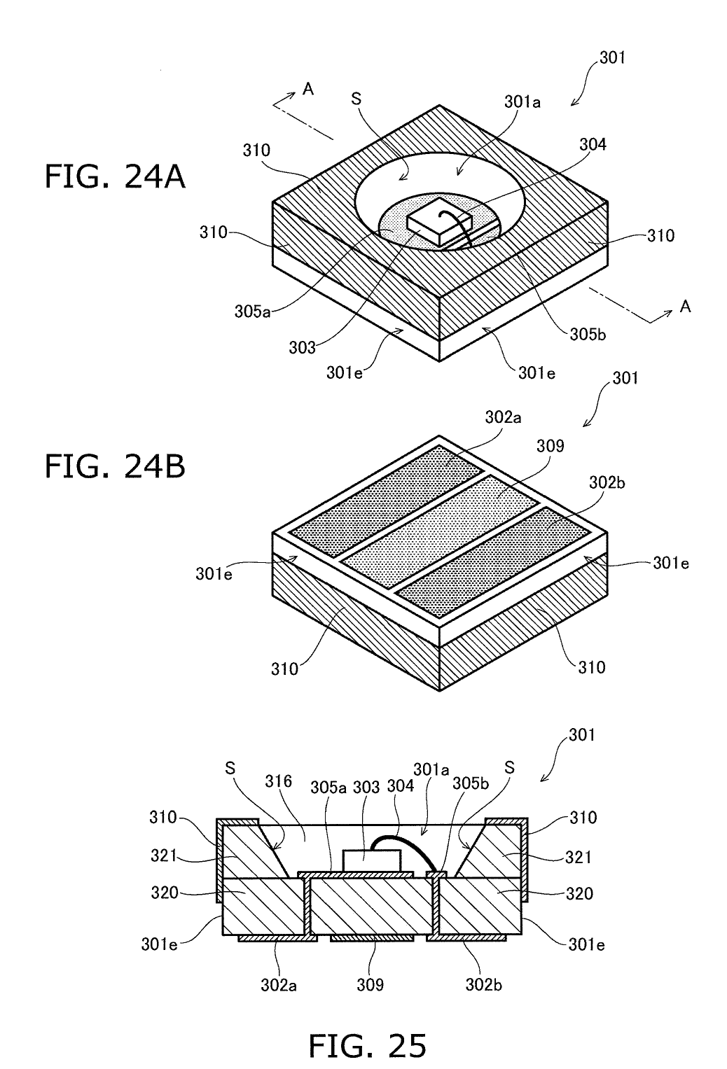

FIG. 24 is a schematic perspective view showing a light emitting device of a second example of this embodiment. More specifically, FIG. 24A is a perspective view of the light emitting device as viewed from the light extraction surface side, and FIG. 24B is a perspective view of the light emitting device as viewed from the side opposite to the light extraction surface.

FIG. 25 is a cross-sectional view taken along line A-A of FIG. 24A. In FIG. 24 and the following figures, the elements similar to those shown in earlier figures are labeled with the same reference numerals, and the detailed description thereof is omitted as appropriate.

In this example, the side surface of the package 301 includes, on a portion close to the mounting surface, an exposed portion 301e which is not coated with the reflecting film 310. For example, in the case where the reflecting film 310 formed from a metal or other conductive material extends close to the mounting surface of the package 301, when the light emitting device is mounted on a mounting substrate, not shown, the mounting electrode of the mounting substrate may electrically short-circuit to the reflecting film 310. In particular, when the light emitting device is mounted on the mounting substrate, if a solder, conductive adhesive or the like runs off around the light emitting device, it is likely to be in contact with the reflecting film 310 coating the side surface. Thus, if the mounting electrodes 302a and 302b are short-circuited through the reflecting film 310, the device becomes inoperable.

In contrast, according to this example, on the side surface of the package 301, the portion close to the mounting surface is provided with no reflecting film 310. This can prevent electrical short circuit even if a solder, conductive adhesive or the like runs off around the light emitting device when the light emitting device is mounted.

Furthermore, as seen in FIG. 25, the light emitting element 303 is normally placed at a relatively higher position in the package 301. That is, the light emitted from the light emitting element 303 and introduced from the inner wall surface S into the frame 321 and the substrate 320 only slightly leaks from the exposed portion 301e, and can be mostly reflected back into the recess 301a by the reflecting film 310.

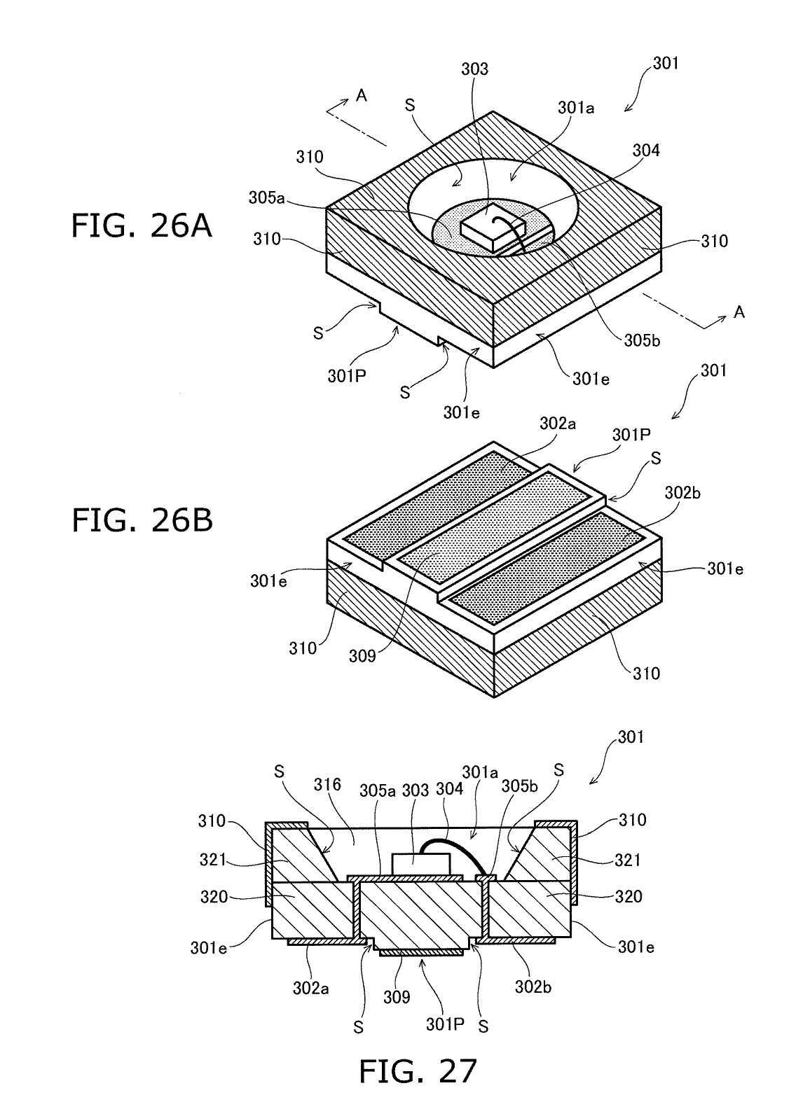

FIG. 26 is a schematic perspective view showing a light emitting device of a third example of this embodiment. More specifically, FIG. 26A is a perspective view of the light emitting device as viewed from the light extraction surface side, and FIG. 26B is a perspective view of the light emitting device as viewed from the side opposite to the light extraction surface.

FIG. 27 is a cross-sectional view taken along line A-A of FIG. 26A.

In this example, a projection (mounting surface) 301P is formed on the mounting surface of the package 301. The projection 301P is formed between the mounting electrodes 302a and 302b, and a heat sink metal 309 is provided thereon. That is, the mounting electrodes 302a and 302b serving as feeder electrode surfaces are set back from the heat sink metal 309 on the mounting surface side, and a step difference S is provided therebetween.

This achieves an effect similar to that of the step difference S (see FIG. 1) described above with reference to the first embodiment. More specifically, the package 301 can be mounted on a mounting member such as a substrate in close contact therewith out being lifted by solder. Furthermore, as described above with reference to FIG. 4, the projection 301P thus provided allows the solder to flow below the mounting electrodes 302a and 302b so that, advantageously, the mounting position of the light emitting device can be automatically corrected to a prescribed position.

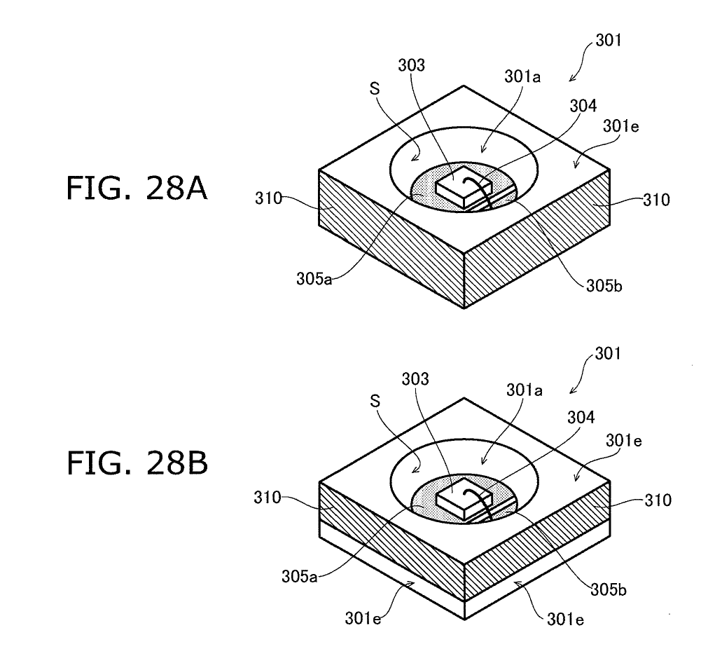

FIGS. 28A and 28B are schematic perspective views showing a light emitting device of a fourth and fifth example of this embodiment, respectively.

In the fourth example shown in FIG. 28A, on the outer wall surface of the package 301, the side surface is provided with a reflecting film 310, whereas the upper surface is not provided with the reflecting film 310, but left as an exposed portion 301e. Also in this case, lateral light leakage can be prevented, and light can be extracted only upward, that is, in the direction where the recess 301a is provided.

In the fifth example shown in FIG. 28B, the upper surface of the package 301 is again left as an exposed portion 301e where the reflecting film 310 is not provided. Furthermore, an exposed portion 301e is also provided on a portion of the side surface close to the mounting surface. Thus, as described above with reference to the second example, short circuit can be prevented also when the light emitting device is mounted.

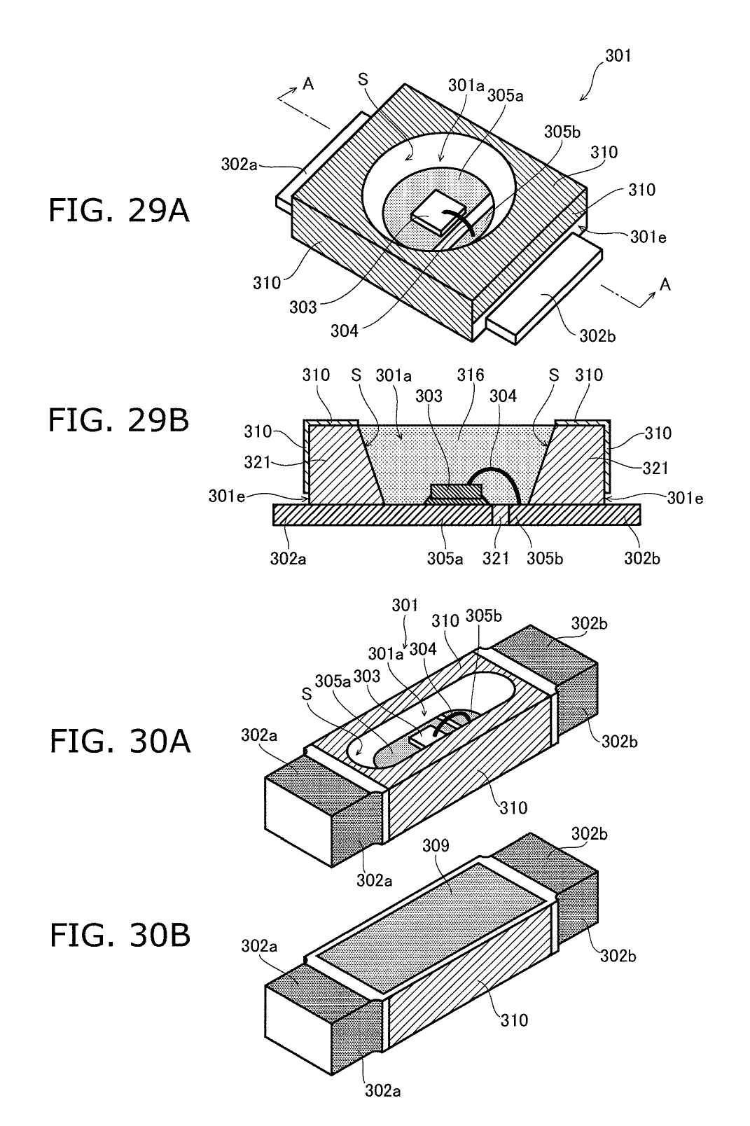

FIG. 29A is a schematic perspective view showing a light emitting device of a sixth example of this embodiment, and FIG. 29B is a cross-sectional view taken along line A-A thereof.

In this example, the mounting electrodes 302a and 302b protrude from the side surface of the package 301. The package 301 like this can be formed illustratively by embedded molding, where the mounting electrodes 302a and 302b formed in a lead frame are embedded in a resin preform, which is then molded.

In this structure, when the reflecting film 310 is formed from a metal or other conductive material, according to this example, the portion close to the mounting electrodes 302a and 302b is not provided with the reflecting film 310, but left as an exposed portion 301e. Thus, short circuit between the mounting electrodes 302a and 302b can be prevented. Furthermore, in this example, no exposed portion 301e is provided on the side surfaces orthogonal to the side surfaces from which the mounting electrodes 302a and 302b protrude, but the former side surfaces are entirely coated with the reflecting film 310. However, in the case where the reflecting film 310 on the former side surfaces is in danger of short circuit to any electrode pattern of a mounting substrate or the like on which this light emitting device is mounted, as shown in FIG. 28B, it is possible to form an exposed portion 301e in the vicinity of the mounting surface without providing the reflecting film 310 thereon.

FIG. 30 is a schematic perspective view showing a light emitting device of a seventh example of this embodiment. More specifically, FIG. 30A is a perspective view of the light emitting device as viewed from the light extraction surface side, and FIG. 30B is a perspective view of the light emitting device as viewed from the side opposite to the light extraction surface.

In this example, at both longitudinal ends of the package 301 shaped like a generally rectangular parallelepiped, mounting electrodes 302a and 302b are provided around the package 301. These mounting electrodes 302a and 302b are respectively connected to the lead electrodes 305a and 305b provided at the bottom of the recess 301a having a flat opening shape. On the outer wall surface of the package 301, the surface having the recess 301a and the surfaces orthogonal thereto are provided with a reflecting film 310. On the other hand, a heat sink metal 309 for heat dissipation is provided on the backside opposite to the surface having the recess 301a. Also in this example, the reflecting film 310 thus provided allows light emitted from the light emitting element 303 and introduced from the inner wall surface S into the package 301 to be reflected back into the recess 301a by the reflecting film 310. Consequently, even if downsized, light leakage from other than the recess 301a is prevented, and light can be extracted from the recess 301a with high brightness.

This example can be mounted on a substrate or the like with the heat sink metal 309 used as a mounting surface. However, in addition, this example can be used as a so-called “side view type” light emitting device.

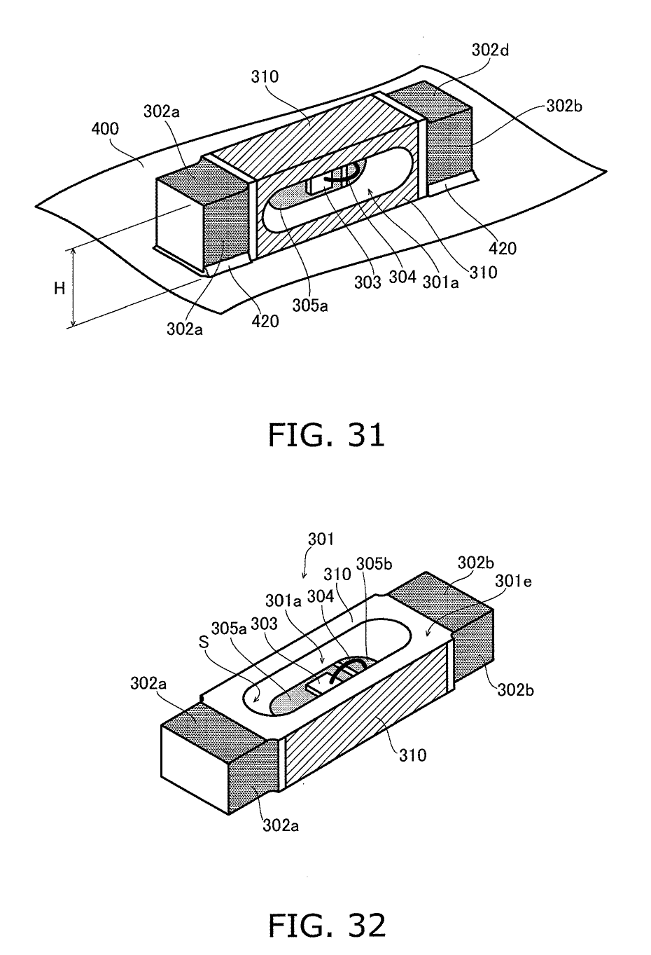

FIG. 31 is a schematic view showing the mounted state of the light emitting device of this example being in use as a side view type device.

In the case where the light emitting device of this example is used as a side view type device, the mounting electrodes 302a and 302b can be mounted on a mounting member 400 such as a mounting substrate using a solder 420, with the recess 301a directed laterally. For example, when in use as a backlight of a liquid crystal display, a light guide plate is adjacently juxtaposed at the frontside (opposed to the surface having the recess 301a) of the light emitting device thus mounted, and light emitted from the light emitting device can be incident on the side surface of the light guide plate with high efficiency. Thus, an ultrathin, high-brightness backlight can be realized, in which the light guide plate and the light emitting device both have a height H of 1 millimeter or less. Furthermore, in this example, even in the case where the light emitting device has such a very small height H, the reflecting film 310 provided therein can prevent light leakage from other than the recess 301a, and light emission with high brightness can be obtained from the recess 301a.

Furthermore, in the state where the light emitting device is thus mounted on the mounting member 400, a heat sink or the like, not shown, can be connected to the heat sink metal 309 provided on the side opposite to the recess 301a. Thus, heat dissipated from the semiconductor light emitting element 303 can be efficiently dissipated outside through the large heat sink metal 309 provided immediately on the backside thereof.

FIG. 32 is a schematic perspective view showing a light emitting device of an eighth example of this embodiment. This example has a structure similar to that of the seventh example described above with reference to FIGS. 30 and 31. However, this example is different in that the surface having the recess 301a is not provided with the reflecting film 310, but left as an exposed portion 301e. Also in this case, it is possible to prevent light leakage in the lateral direction with respect to the surface having the recess 301a, and light can be extracted with high efficiency from the surface having the recess 301a.

Next, a method for forming the reflecting film 310 is described.

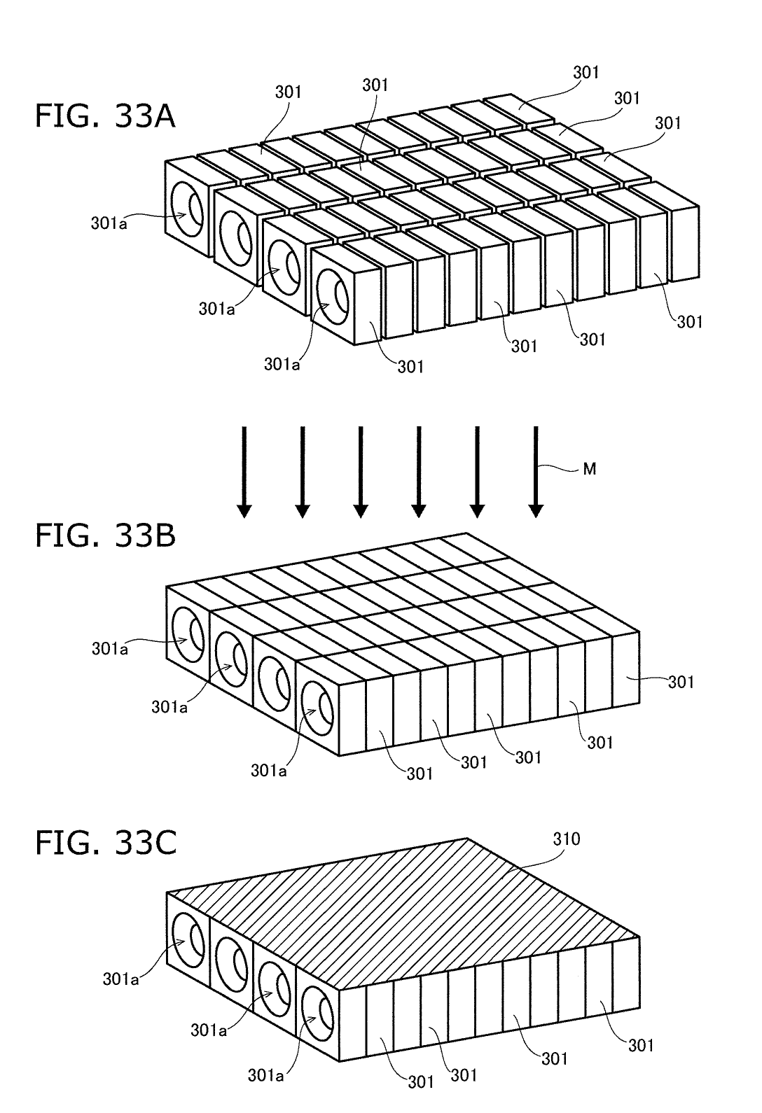

FIG. 33 is a process view illustrating the method for forming the reflecting film 310 on the side surface of the package 301. First, as shown in FIG. 33A, a plurality of packages 301 are arranged so that the surface to be provided with the reflecting film 310 is directed to a particular direction.

Then, as shown in FIG. 33B, these packages 301 are fixed using a jig or the like, and a material M to constitute the reflecting film 310 is supplied to this surface. As an example method therefor, a silver paste or the like is applied using a printer, and then burned to evaporate the resin component. Thus, a silver reflecting film 310 is formed as shown in FIG. 33C.

Alternatively, in this state of being fixed with a jig, the packages 301 are placed in a vacuum chamber, and as shown in FIG. 33B, a material M such as silver is deposited by evaporation, sputtering or the like. Thus, the reflecting film 310 can be formed as shown in FIG. 33C.

Alternatively, an aluminum or other metal foil may be stuck using an adhesive or the like. Here, a relatively thin metal foil can be used. Then, after the metal foil is stuck as shown in FIG. 33C, when the jig is detached and individual packages 301 are separated, the metal foil can be cut at the junction between the packages 301, whereas the metal foil remains attached to each package 301.

The reflecting film 310 can be formed on another surface of the package 301 by rearranging the packages 301 and repeating the process described above with reference to FIG. 33. By thus repeating the process, the reflecting film 310 can be provided on any outer wall surface as required.

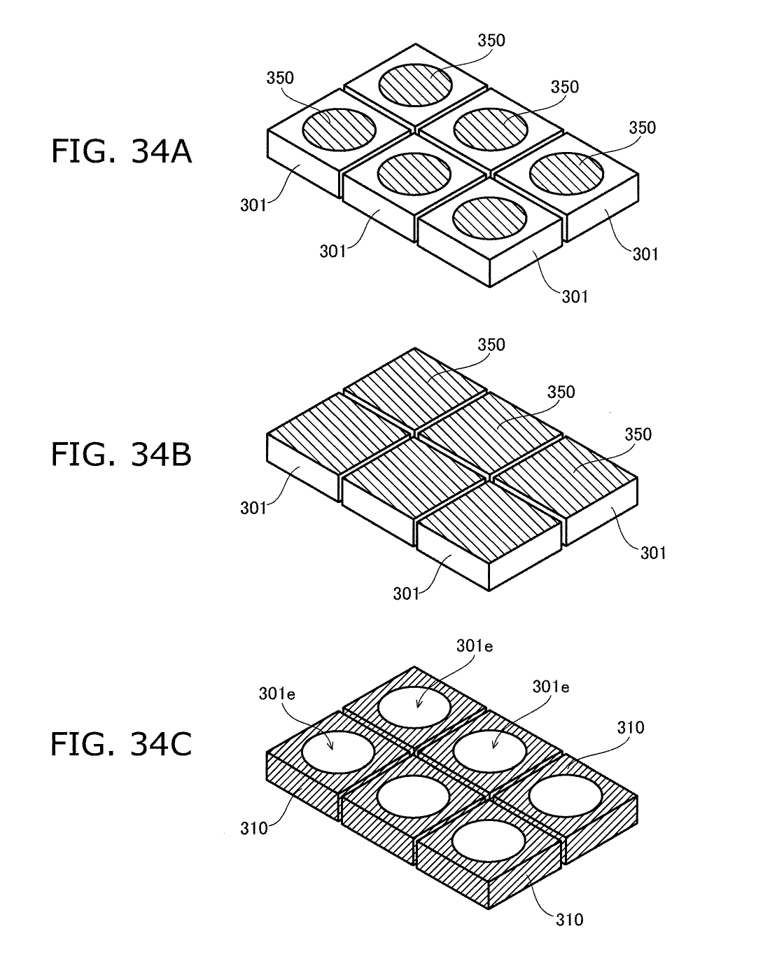

FIG. 34 is a process view showing a method for using a mask. Here, FIGS. 34A and 34C show the upper surface side of the packages 301, and FIG. 34B shows the rear surface side of the packages 301.

First, as shown in FIGS. 34A and 34B, a mask 350 is previously formed using a photoresist or the like on a portion of the surface of the packages 301 where the reflecting film 310 is not to be formed. Then, the packages 301 are placed in a vacuum chamber, and the reflecting film 310 made of silver or the like is deposited by evaporation or sputtering on the upper surface and the side surface of the packages 301 while rotating and revolving the packages 301 being tilted, for example. Subsequently, the mask 350 is removed by a photoresist remover or the like to lift off the reflecting film 310 deposited thereon. Thus, the reflecting film 310 can be formed in a prescribed pattern as shown in FIG. 34C.

Alternatively, a mask 350 is formed using a fluororesin-based material or the like as shown in FIGS. 34A and 34B, and dipped into a silver paste. The silver paste is repelled on the mask 350, which is not coated therewith. Subsequently, the mask 350 is removed, followed by burning. Then, the reflecting film 310 can be formed in a prescribed pattern as shown in FIG. 34C.

The second embodiment of the invention has been described with reference to examples. However, the invention is not limited to these examples. For instance, those skilled in the art can suitably modify the substrate, frame, recess, light emitting element, lead electrode, mounting electrode, heat sink metal, wire, resin and the like constituting the light emitting device of the invention, and such modifications are also encompassed within the scope of the invention as long as they fall within the spirit of the invention.

### INDUSTRIAL APPLICABILITY

This invention can provide a light emitting device allowing higher brightness and thinner profile, and its manufacturing method and its mounted substrate.

Additionally, this invention can provide a light emitting device capable of efficiently emitting light in the emitting direction by using a diffuse reflecting surface and preventing light leakage from the package.

1. A light emitting device comprising:
a package including a generally quadrangular light emitting surface with a recess formed therein, a rear surface opposed to the light emitting surface, a first side surface generally orthogonal to the light emitting surface and the rear surface, and a second side surface opposed to the first side surface; and
a light emitting element provided in the recess,
at least one of the first side surface and the rear surface including a first and second feeder electrode surfaces connected to the light emitting element and a mounting surface provided between the first feeder electrode surface and the second feeder electrode surface,
a step difference being provided between the first feeder electrode surface and the mounting surface,
a step difference being provided between the second feeder electrode surface and the mounting surface, and
the first and second feeder electrode surfaces being set back from the mounting surface adjacent thereto.

2. The light emitting device according to claim 1, wherein
the first and second feeder electrode surfaces and the mounting surface are provided on the first side surface, and
the first side surface further includes a protrusion provided at least one of both ends outside the first and second feeder electrode surfaces and a position dividing the first and second feeder electrode surfaces, the protrusion protruding to a plane generally coplanar with the mounting surface.

3. The light emitting device according to claim 1, wherein
the first and second feeder electrode surfaces and the mounting surface are provided on the first side surface,
the light emitting surface is provided with a first light emitting surface electrode connected to the first feeder electrode surface and a second light emitting surface electrode connected to the second feeder electrode surface, and
the rear surface is provided with a first rear surface electrode connected to the first feeder electrode surface and a second rear surface electrode connected to the second feeder electrode surface.

4. The light emitting device according to any one of claims 1 to 3, wherein
the first and second feeder electrode surfaces and the mounting surface are provided on the first side surface,
the second side surface includes a third feeder electrode surface provided at one end thereof and connected to the first feeder electrode surface, and a fourth feeder electrode surface provided at the other end thereof and connected to the second feeder electrode surface, and
at least one of the first to fourth feeder electrode surfaces is different in shape from the others.

5. A manufacturing method for a light emitting device which includes a package including a light emitting surface with a recess formed therein and a first side surface being generally orthogonal to the light emitting surface and having a first and second feeder electrode surfaces, and a light emitting element provided in the recess, the manufacturing method comprising:
forming the first and second feeder electrode surfaces by forming a conductive layer on an inner wall of a plurality of through holes formed in a base body which includes the recess in a plurality.

6. A manufacturing method for a light emitting device, comprising:
forming a conductive layer on an inner wall of a through hole in a base body which includes the recess and a through hole in a plurality;
mounting a light emitting element in the recess;
connecting a lead electrode provided in the recess to the light emitting element by a bonding wire;
filling the recess with a resin; and
cutting the base body along a line connecting the through holes.

7. The manufacturing method for a light emitting device according to claim 5, wherein the height of a step difference formed between a cut surface exposed by the cutting and the conductive layer formed on the inner wall of the through hole is regulated by adjusting at least one of the position of the cutting and the thickness of a blade used for cutting.

8. A mounted substrate comprising:
a substrate;
a first and second land electrodes provided on the substrate; and
the light emitting device according to any one of claims 1 to 4 provided on the substrate,
the first feeder electrode surface of the light emitting device being connected to the first land electrode, and
the second feeder electrode surface of the light emitting device being connected to the second land electrode.

9. A light emitting device comprising:
a package including a resin or ceramic with a recess formed therein; and
a light emitting element provided in the recess,
an outer wall surface of the resin or ceramic being provided with a reflecting film.

10. A light emitting device comprising:
a package made of a resin or ceramic and including a light emitting surface with a recess formed therein and a side surface adjacent to the light emitting surface; and
a light emitting element provided in the recess,
the side surface being provided with a reflecting film.

11. The light emitting device according to claim 10, wherein the light emitting surface is also provided with a reflecting film.

12. The light emitting device according to any one of claims 9 to 11, wherein the reflecting film is one selected from the group consisting of a metal film, a film containing metal oxide fine particles, and a multilayer film made of a dielectric.
